(19) United States
(12) Patent Application Publication
(10) Pub. No.: US 2009/0235974 A1
(43) Pub. Date: Sep. 24, 2009

(54) SOLAR CONCENTRATOR AND DEVICES AND METHODS USING THEM

(75) Inventors: Jonathan Mapel, East Boston, MA (US); Michael Currie, Groton, MA (US); Timothy D. Heidel, Cambridge, MA (US); Marc Baldo, Cambridge, MA (US); Shalom Goffri, Boston, MA (US)

Correspondence Address: LANDO & ANASTASI, LLP, ONE MAIN STREET, SUITE 1100, CAMBRIDGE, MA, 02142, US

(73) Assignee: MASSACHUSETTS INSTITUTE OF TECHNOLOGY, Cambridge, MA (US)

(21) Appl. No.: 12/353,459

(22) Filed: Jan. 14, 2009

Related U.S. Application Data
(60) Provisional application No. 61/020,946, filed on Jan. 14, 2008.

(51) Int. Cl. H01L 31/052

(52) U.S. Cl. 136/246; 136/259

(57) ABSTRACT

Solar concentrators are disclosed that improve the efficiency of PV cells and systems using them. The solar concentrators may be designed such that they include one or more chromophores that emit light to a PV cell. Various materials and components of the solar concentrators are also described.

### PRIORITY APPLICATION

This application claims priority to U.S. Provisional Application No. 61/020,946 filed on Jan. 14, 2008, the entire disclosure of which is hereby incorporated herein by reference for all purposes.

### GOVERNMENT SUPPORT

Certain embodiments of the technology disclosed herein may have been developed, at least in part, under Grant Nos. OR 5653-001.01 and DE-FG02-07ER46474. The government may have certain rights in the technology.

### FIELD OF THE TECHNOLOGY

Certain embodiments of the technology disclosed herein relate generally to solar concentrators and devices and methods using them. More particularly, certain examples disclosed herein are directed to solar concentrators that may be produced at a lower cost.

### BACKGROUND

Solar cells may be used to convert solar energy into electrical energy. Many solar cells are inefficient, however, with a small fraction of the incident solar energy actually being converted into a usable current. Also, the high cost of solar cells limits their use as a renewable energy source.

### SUMMARY

In accordance with a first aspect, a solar concentrator is disclosed. In certain examples, the solar concentrator may comprise a substrate and at least first and second closely spaced chromophores disposed on or in the substrate in a manner to receive at least some optical radiation is disclosed. In some example, the first chromophore can be effective to absorb at least one wavelength of at least some of the optical radiation and further effective to transfer energy by Förster energy transfer to the second chromophore. In certain examples, the second chromophore can be effective to emit the transferred energy at a wavelength that is red-shifted from the wavelength absorbed by the first chromophore.

In certain embodiments, the substrate may be a glass comprising a refractive index of at least 1.7. In other embodiments, the second chromophore may emit light by phosphorescence. In certain examples, the solar concentrator may further comprise an effective amount of a red-shifting agent to shift an emission wavelength range of the second chromophore to a higher wavelength range. In additional examples, at least one of the first and second chromophores may be an organometallic compound. In some embodiments, the organometallic compound may be a porphyrin compound. In other embodiments, the solar concentrator may further comprise at least one wavelength selective mirror disposed on the substrate, the wavelength selective mirror configured to transmit incident light in one wavelength range and to reflect incident light in another wavelength range. In some examples, the solar concentrator may further comprise a polar matrix in which at least one of the first and second chromophores is disposed. In certain embodiments, the solar concentrator may further comprise a first photovoltaic cell optically coupled to the solar concentrator. In other embodiments, the solar concentrator may further comprise a second photovoltaic cell optically coupled to the solar concentrator, wherein the efficiency of the first and second photovoltaic cells is different.

In accordance with another aspect, a solar concentrator comprising a substrate and a plurality of chromophores disposed on or in the substrate in a manner to receive at least some optical radiation is provided. In some examples, the plurality of chromophores each can be effective to absorb at least one wavelength of at least some of the optical radiation without substantial light emission of the absorbed optical radiation. In certain examples, the film comprises a terminal chromophore effective to receive at least some of the absorbed radiation from the plurality of chromophores, the terminal chromophore effective to emit at least some of the received energy at a wavelength that is red-shifted from the at least one wavelength absorbed by the plurality of chromophores.

In certain embodiments, the substrate may be a glass comprising a refractive index of at least 1.7. In other embodiments, the terminal chromophore may be selected to emit light by phosphorescence. In some examples, the solar concentrator may further comprise an effective amount of a red-shifting agent to shift an emission wavelength range of the terminal chromophore to a higher wavelength range. In other examples, at least one of the plurality of chromophores may be an organometallic compound. In certain examples, the organometallic compound may be a porphyrin compound. In additional examples, the solar concentrator may further comprise at least one wavelength selective mirror disposed on the substrate, the wavelength selective mirror configured to transmit incident light in one wavelength range and to reflect incident light in another wavelength range. In other examples, the solar concentrator may further comprise a polar matrix in which at least one of the plurality of chromophores is disposed. In certain embodiments, the solar concentrator may further comprise a first photovoltaic cell optically coupled to the solar concentrator. In other embodiments, the solar concentrator may further comprise a second photovoltaic cell optically coupled to the solar concentrator, wherein the efficiency of the first and second photovoltaic cells is different.

In accordance with an additional aspect, a solar concentrator comprising a substrate and a film disposed on the substrate in a manner to receive at least some optical radiation, the film comprising at least a first chromophore and a second chromophore is provided. In certain examples, the first chromophore can be effective to absorb at least one wavelength of at least some of the optical radiation and further effective to transfer at least some of the energy by Förster energy transfer to the second chromophore. In other examples, the second chromophore can be effective to emit at least some of the transferred energy at a wavelength that is red-shifted from the wavelength absorbed by the first chromophore is disclosed.

In certain embodiments, the substrate may be a glass comprising a refractive index of at least 1.7. In other embodiments, the second chromophore may be selected to emit light by phosphorescence. In some examples, the solar concentrator may further comprise an effective amount of a red-shifting agent to shift an emission wavelength range of the second chromophore to a higher wavelength range. In other examples, at least one of the chromophores may be an organometallic compound. In additional examples, the organometallic compound may be a porphyrin compound. In certain examples, the solar concentrator may further comprise at least one wavelength selective mirror disposed on the substrate, the wavelength selective mirror configured to transmit incident light in one wavelength range and to reflect incident light in another wavelength range. In other examples, the solar concentrator may further comprise a polar matrix in which at least one of the chromophores is disposed. In certain embodiments, the solar concentrator may further comprise a first photovoltaic cell optically coupled to the solar concentrator. In some embodiments, the solar concentrator may further comprise a second photovoltaic cell optically coupled to the solar concentrator, wherein the efficiency of the first and second photovoltaic cells is different.

In accordance with another aspect, a solar concentrator comprising a substrate and a film disposed on the substrate in a manner to receive at least some optical radiation, the film comprising a plurality of chromophores each effective to absorb at least one wavelength of at least some of the optical radiation without substantial light emission of the absorbed optical radiation is provided. In certain examples, the film further comprises a terminal chromophore effective to receive at least some of the absorbed radiation from the plurality of chromophores, the terminal chromophore effective to emit at least some of the received energy at a wavelength that is red-shifted from the at least one wavelength absorbed by the plurality of chromophores.

In certain embodiments, the substrate may be a glass comprising a refractive index of at least 1.7. In other embodiments, the terminal chromophore may be selected to emit light by phosphorescence. In some examples, the solar concentrator may further comprise an effective amount of a red-shifting agent to shift an emission wavelength range of the terminal chromophore to a higher wavelength range. In other examples, at least one of the plurality of chromophores may be an organometallic compound. In some embodiments, the organometallic compound may be a porphyrin compound. In other examples, the solar concentrator may further comprise at least one wavelength selective mirror disposed on the substrate, the wavelength selective mirror configured to transmit incident light in one wavelength range and to reflect incident light in another wavelength range. In certain examples, the solar concentrator may further comprise a polar matrix in which at least one of the plurality of chromophores is disposed. In certain embodiments, the solar concentrator may further comprise a first photovoltaic cell optically coupled to the solar concentrator. In other embodiments, the solar concentrator may further comprise a second photovoltaic cell optically coupled to the solar concentrator, wherein the efficiency of the first and second photovoltaic cells is different.

In accordance with an additional aspect, a solar concentrator comprising a substrate and a film disposed on the substrate in a manner to receive at least some optical radiation, the film comprising at least a first chromophore and a second chromophore is disclosed. In certain examples, the first chromophore can be effective to absorb at least some optical radiation and transfer at least some energy to the second chromophore. In other examples, the second chromophore can be effective to emit at least some of the transferred energy at a wavelength that is red-shifted from a wavelength of optical radiation absorbed by the first chromophore, in which the first chromophore is present in the film at a concentration at least ten times greater than the concentration of the second chromophore in the film.

In certain embodiments, the substrate may be a glass comprising a refractive index of at least 1.7. In some embodiments, the second chromophore may be selected to emit light by phosphorescence. In other embodiments, the solar concentrator may further comprise an effective amount of a red-shifting agent to shift the emission wavelength range of the second chromophore to a higher wavelength. In some examples, at least one of the chromophores may be an organometallic compound. In certain examples, the organometallic compound may be a porphyrin compound. In some embodiments, the solar concentrator may further comprise at least one wavelength selective mirror disposed on the substrate, the wavelength selective mirror configured to transmit incident light in one wavelength range and to reflect incident light in another wavelength range. In certain examples, the solar concentrator may further comprise a polar matrix in which at least one of the chromophores is disposed. In certain embodiments, the solar concentrator may further comprise a first photovoltaic cell optically coupled to the solar concentrator. In some embodiments, the solar concentrator may further comprise a second photovoltaic cell optically coupled to the solar concentrator, wherein the efficiency of the first and second photovoltaic cells is different.

In accordance with another aspect, a solar concentrator comprising a substrate and a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength is disclosed.

In certain embodiments, the substrate may be a glass comprising a refractive index of at least 1.7. In some examples, the ratio of the coefficient at peak absorption wavelength to the absorption coefficient at the peak emission wavelength is greater than or equal to 40. In certain examples, the first and second wavelength ranges overlap by less than 20 nm. In some embodiments, the solar concentrator may further comprise an effective amount of a red-shifting agent to shift the second wavelength range of the material to a higher wavelength. In certain examples, the material comprises an organometallic compound. In some embodiments, the organometallic compound may be a porphyrin compound. In other examples, the solar concentrator may further comprise at least one wavelength selective mirror disposed on the substrate, the wavelength selective mirror configured to transmit incident light in one wavelength range and to reflect incident light in another wavelength range. In some examples, the solar concentrator may further comprise a polar matrix in which the material is disposed. In certain embodiments, the solar concentrator may further comprise a first photovoltaic cell optically coupled to the solar concentrator. In other embodiments, the solar concentrator may further comprise a second photovoltaic cell optically coupled to the solar concentrator, wherein the efficiency of the first and second photovoltaic cells is different.

In accordance with an additional aspect, a solar concentrator comprising a substrate and a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength ranges that is red-shifted from the first wavelength range, the composition further comprising an effective amount of a red-shifting agent to shift the second wavelength range to a higher wavelength range such that the first and second wavelength ranges do not substantially overlap in wavelength is provided.

In certain embodiments, the substrate may be a glass comprising a refractive index of at least 1.7. In some examples, the ratio of the coefficient at peak absorption wavelength to the absorption coefficient at the peak emission wavelength is greater than or equal to 40. In other examples, the red-shifting agent may be effective to shift the second wavelength range by at least 100 nm, e.g., 150 nm or more. In some examples, the material may comprise an organometallic compound. In certain examples, the organometallic compound may be a porphyrin compound. In certain embodiments, the solar concentrator may further comprise at least one wavelength selective mirror disposed on the substrate, the wavelength selective mirror configured to transmit incident light in one wavelength range and to reflect incident light in another wavelength range. In some examples, the solar concentrator may further comprise a polar matrix in which the material is disposed. In certain embodiments, the solar concentrator may further comprise a first photovoltaic cell optically coupled to the solar concentrator. In other embodiments, the solar concentrator may further comprise a second photovoltaic cell optically coupled to the solar concentrator, wherein the efficiency of the first and second photovoltaic cells is different.

In accordance with another aspect, a solar concentrator comprising a substrate and a composition disposed on or in the substrate in a manner to absorb at least some optical radiation, the composition comprising at least one organometallic compound is provided.

In certain embodiments, the substrate may be a glass comprising a refractive index of at least 1.7. In other examples, the organometallic compound may be a porphyrin compound. In some examples, the composition may further comprise a red-shifting agent. In additional examples, the composition may further comprise at least one chromophore. In some embodiments, the composition may further comprise a plurality of chromophores. In other embodiments, the solar concentrator may further comprise at least one wavelength selective mirror disposed on the substrate, the wavelength selective mirror configured to transmit incident light in one wavelength range and to reflect incident light in another wavelength range. In additional examples, the solar concentrator may further comprise a polar matrix in which the organometallic compound is disposed. In certain embodiments, the solar concentrator may further comprise a first photovoltaic cell optically coupled to the solar concentrator. In other embodiments, the solar concentrator may further comprise a second photovoltaic cell optically coupled to the solar concentrator, wherein the efficiency of the first and second photovoltaic cells is different.

In accordance with an additional aspect, a solar concentrator comprising a substrate and a composition disposed on or in the substrate in a manner to absorb at least some optical radiation, the composition comprising at least one organometallic compound effective to absorb the optical radiation within a first wavelength range and to emit the absorbed optical radiation by phosphorescence within a second wavelength range that is red-shifted from the first wavelength range, in which the first and second wavelength ranges do not substantially overlap in wavelength is disclosed.

In certain embodiments, the substrate may be a glass comprising a refractive index of at least 1.7. In other embodiments, the organometallic compound may be a porphyrin compound. In some examples, the composition may further comprise a red-shifting agent. In additional examples, the composition may further comprise at least one chromophore. In other examples, the composition may further comprise a plurality of chromophores. In certain examples, the solar concentrator may further comprise at least one wavelength selective mirror disposed on the substrate, the wavelength selective mirror configured to transmit incident light in one wavelength range and to reflect incident light in another wavelength range. In additional examples, the solar concentrator may further comprise a polar matrix in which the organometallic compound is disposed. In certain embodiments, the solar concentrator may further comprise a first photovoltaic cell optically coupled to the solar concentrator. In some embodiments, the solar concentrator may further comprise a second photovoltaic cell optically coupled to the solar concentrator, wherein the efficiency of the first and second photovoltaic cells is different.

In accordance with another aspect, a solar concentrator comprising a substrate and a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength is provided.

In certain embodiments, the substrate may be a glass comprising a refractive index of at least 1.7. In some embodiments, the organometallic compound may be a porphyrin compound. In certain examples, the red-shifting agent may be effective to shift the emission wavelength range by at least 100 nm. In other examples, the composition may further comprise at least one chromophore. In additional examples, the composition may further comprise a plurality of chromophores. In some examples, the solar concentrator may further comprise at least one wavelength selective mirror disposed on the substrate, the wavelength selective mirror configured to transmit incident light in one wavelength range and to reflect incident light in another wavelength range. In certain embodiments, the solar concentrator may further comprise a polar matrix in which the organometallic compound is disposed. In other embodiments, the solar concentrator may further comprise a first photovoltaic cell optically coupled to the solar concentrator. In additional embodiments, the solar concentrator may further comprise a second photovoltaic cell optically coupled to the solar concentrator, wherein the efficiency of the first and second photovoltaic cells is different.

In accordance with an additional aspect, a solar concentrator comprising a substrate and a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range is provided. In some examples, the composition further comprises an effective amount of a red-shifting agent complexed to the organometallic compound to shift the second wavelength range to higher wavelength range such that the first and second wavelength ranges do not substantially overlap in wavelength.

In certain embodiments, the substrate may be a glass comprising a refractive index of at least 1.7. In certain examples, the organometallic compound may be a porphyrin compound. In some embodiments, the red-shifting agent is effective to shift the emission wavelength range by at least 100 nm. In additional examples, the composition further comprises at least one chromophore. In some examples, the composition may further comprise a plurality of chromophores. In certain embodiments, the solar concentrator may further comprise at least one wavelength selective mirror disposed on the substrate, the wavelength selective mirror configured to transmit incident light in one wavelength range and to reflect incident light in another wavelength range. In some embodiments, the solar concentrator may further comprise a polar matrix in which the organometallic compound is disposed. In certain examples, the solar concentrator may further comprise a first photovoltaic cell optically coupled to the solar concentrator. In other examples, the solar concentrator may further comprise a second photovoltaic cell optically coupled to the solar concentrator, wherein the efficiency of the first and second photovoltaic cells is different.

In accordance with another aspect, a solar concentrator comprising a substrate and a first chromophore and a second chromophore disposed on or in the substrate, wherein the first chromophore is oriented at an angle to increase absorption of light incident on the substrate and the second chromophore is oriented at an angle to increase light-trapping efficiency of the solar concentrator is disclosed. In some examples, the first chromophore can transfer energy to the second chromophore which emits light. In some examples, the solar concentrator may be optically coupled to a first photovoltaic cell. In other examples, a second photovoltaic cell may be optically coupled to the solar concentrator, wherein the efficiency of the first and second photovoltaic cells may be different.

In accordance with an additional aspect, a tandem device comprising a solar concentrator and a thin film photovoltaic cell is provided. In some examples, a higher electrical bandgap of the concentrator solar cell allows a higher fraction of each photon's optical energy to be converted to electrical energy, such that the power conversion efficiency can be increased compared to the configuration where the thin film photovoltaic cell operates alone.

Additional features, aspects, examples and embodiments are possible and will be recognized by the person of ordinary skill in the art, given the benefit of this disclosure.

### BRIEF DESCRIPTION OF THE FIGURES

Certain illustrative features, aspects, examples and embodiments are described below with reference to the figures in which:

FIG. 1 is an illustration of one embodiment of a solar concentrator, in accordance with certain examples;

FIGS. 2A and 2B show the absorption and emission spectra of two chromophores, in accordance with certain examples;

FIGS. 3A and 3B are schematics showing thin films disposed on a substrate, in accordance with certain examples;

FIG. 4 shows absorption and emission spectra for a chromophore, in accordance with certain examples;

FIG. 5 shows an absorption spectrum, a fluorescence emission spectrum and a phosphorescence emission spectrum, in accordance with certain examples;

FIG. 6 illustrate red-shifting of an emission spectrum, in accordance with certain examples;

FIG. 7 is a schematic of a substrate comprising wavelength selective mirrors disposed on opposite surfaces, in accordance with certain examples;

FIG. 8 is a schematic of a device that include a PV cell embedded in a waveguide, in accordance with certain examples;

FIG. 9 is graph showing the absorption and emission spectra for a chromophore doped with DCTJB, in accordance with certain examples;

FIG. 10 is a graph showing the efficiencies of various chromophores, in accordance with certain examples;

FIG. 11 is a graph showing an increase in Förster energy transfer by doping a chromophore with another material, in accordance with certain examples;

FIG. 12 is a schematic of an embodiment of a tandem solar concentrator, in accordance with certain examples;

FIG. 13 is a graph showing predicted performance of the solar concentrator of FIG. 12, in accordance with certain examples;

FIG. 14 is a schematic showing a solar concentrator with a dessicant layer, in accordance with certain examples;

FIG. 15 is a schematic of another embodiment of a tandem solar concentrator, in accordance with certain examples;

FIG. 16 is a schematic of a packaged solar concentrator, in accordance with certain examples;

FIG. 17 is another schematic of a packaged solar concentrator, in accordance with certain examples;

FIG. 18A is a graph showing the self-absorption ratio in a DCJTB-based solar concentrator is S=80 (dotted lines); a larger self-absorption ratio of S=220 is obtained in a rubrene-based concentrator (solid lines), because the amount of DCJTB is reduced by a factor of three; its absorption is replaced by rubrene, which then transfers energy to DCJTB (see FIG. 18C); the inset of FIG. 18A shows the DCJTB chemical structure;

FIG. 18B is a graph showing phosphorescence emission (FIG. 18D) to reduce self-absorption; the self-absorption ratio in a Pt(TPBP)-based concentrator is S=500; the inset of FIG. 18B shows the Pt(TPBP) chemical structure;

FIG. 18C is a diagram showing energy transfer; near field dipole-dipole coupling can efficiently transfer energy between host and guest molecules; the guest molecule concentration can be less than 1%, significantly reducing self-absorption;

FIG. 18D is a diagram showing phosphoresence emission; spin orbit coupling in a phosphor increases the PL efficiency of the triplet state and the rate of intersystem crossing from singlet to triplet manifolds; the exchange splitting between singlet and triplet states is typically about 0.7 eV, significantly reducing self-absorption;

FIG. 19A shows the optical quantum efficiency (OQE) spectra of the DCJTB, rubrene and Pt(TPBP)-based single waveguide concentrators;

FIG. 19B shows the results from a tandem configuration where light is incident first on the rubrene-based OSC (blue); this filters the incident light incident on the second, mirror-backed, Pt(TPBP)-based concentrator (green). The composite OQE is shown in red;

FIGS. 20A and 20B shows graphs of concentrator efficiency and flux gain as a function of geometric gain; in FIG. 20A, with increasing G, photons must take a longer path to the edge-attached PV, increasing the probability of re-absorption; in FIG. 20B flux gain compares the electrical power output from the solar cell when attached to the concentrator relative to direct solar illumination; the flux gain increases with G, but reaches a maximum when the benefit of additional G is cancelled by self-absorption losses; near field energy transfer and phosphorescence substantially improve the flux gain relative to the DCJTB-based OSC; and

FIG. 21 shows an example of a tandem device, in accordance with certain examples.

It will be recognized by the person of ordinary skill in the art, given the benefit of this disclosure, that the dimensions of certain elements in the figures may have been enlarged, distorted or otherwise shown in a non-conventional manner to provide a more user-friendly description of the technology. In particular, the relative dimensions and thicknesses of the different components in the light emitting devices are not intended to be limited by those shown in the figures.

### DETAILED DESCRIPTION

Certain embodiments of the solar concentrators and devices using them that are disclosed herein provide significant advantages over existing devices including higher efficiencies, fewer components, and improved materials and improved optical properties. These and other advantages will be recognized by the person of ordinary skill in the art, given the benefit of this disclosure. Certain examples of the solar concentrators disclosed herein may be used with low cost solar cells that comprise amorphous or polycrystalline thin films.

Certain materials or components are described herein as being disposed on or in another material or component. The term dispose is intended to be interchangeable with the term deposit and includes, but is not limited to, evaporation, co-evaporation, coating, painting, spraying, brushing, vapor deposition, casting, covalent association, non-covalent association, coordination or otherwise attachment, for at least some time, to a surface. Illustrative methods of disposing a selected component of the solar concentrators disclosed herein are described in more detail below.

In certain examples, the devices and methods disclosed herein are operative to absorb and/or transfer at least some energy. The phrase “at least some” is used herein in certain instances to indicate that not necessarily all of the energy incident on the substrate is absorbed, not necessarily all of the energy is transferred, or not necessarily the energy that is transferred is all emitted as light. Instead, a portion or fraction of the energy may be lost as heat or other non-radiative processes, for example, in the solar concentrators disclosed herein.

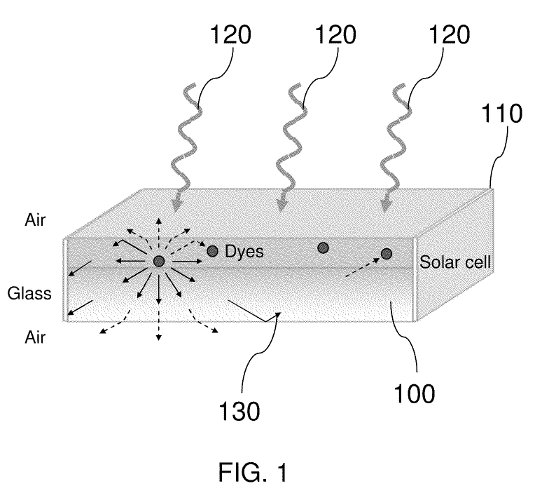

In accordance with certain examples, a luminescent solar concentrator (LSC) separates the photovoltaic functions of light collection and charge separation. For example, light may be gathered by an inexpensive collector that comprises a light absorbing material. The collected light may be focused onto a smaller area of a photovoltaic (PV) cell. The ratio of the area of the collector to the area of the PV cell is known as the geometric concentration factor, G. One attraction of the light concentrator approach is that the complexity of a large area solar cell is replaced by a simple optical collector. PV cells are still used, but large G values of a light concentrator coupled to a PV cell can reduce the PV cost, potentially lowering the overall cost per watt of generated power. An illustrative schematic of a luminescent solar concentrator (LSC) is shown in FIG. 1. The LSC comprises a substrate 100 that includes one or more light absorbing materials disposed on or in the substrate 100. The substrate 100 is optically coupled to at least one solar cell (also referred to as PV cell) at the edge 110 of the substrate 100. Solar radiation 120 is incident on the substrate 100 where it is absorbed by the light absorbing material(s) in the substrate 100. Energy may be re-radiated (see arrows 130) within the substrate 100, and the re-radiated energy may be guided toward the edge 110 for collection by the PV cells. One advantage of using LSC's over PV concentration systems, e.g., mirrors, lenses, dishes and the like, is that very high concentration factors may be achieved without cooling or mechanical tracking.

In certain embodiments, the chromophore that is used in the solar concentrators described herein and that emits light can be a material that is selected from the group consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, prradines, indocyanine green, styryls (Lambdachrome series), dioxazines, naphthalimides, thiazines, stilbenes, IR132, IR144, IR140, Dayglo Sky Blue (D-286), Columbia Blue (D-298), and organometallic complexes of rare earth metals (such as europium, neodymium, and uranium, such as, for example, those described in C. Adachi, M. A. Baldo, S. R. Forrest, Journal of Applied Physics 87, 8049 (2000); K. Kuriki, Y. Koike, Y. Okamoto, Chemical Reviews 102, 2347 (2002); H. S. Wang, et al, Thin Solid Films 479, 216 (2005); Y. X. Ye, et al, Acta Physica Sinica 55, 6424 (2006).

In accordance with certain examples, the solar concentrators disclosed herein may include a substrate that is operative to trap and/or guide light. The terms substrate and waveguide may be interchanged for the purposes of this disclosure. Such trapped light may be directed to or otherwise coupled to a PV cell such that the light may be converted into a current by the PV cell. The substrate need not be in direct sunlight but instead, may be used to receive direct, indirect and diffuse solar radiation. In some examples as discussed below, the substrate may be selected such that one or more chromophores may be disposed in or on the substrate or the substrate may be impregnated with the chromophore. The chromophore may be any substance that can absorb and/or emit light of a desired or selected wavelength. Any material that can receive a chromophore may be used in the substrates of the solar concentrators described herein.

In accordance with certain examples, the substrate may include a material whose refractive index is greater than 1.7. Illustrative materials for use in the substrates of the solar concentrators disclosed herein include, but are not limited to, polymethylmethyacrylate (PMMA), glass, lead-doped glass, lead-doped plastics, aluminum oxide, polycarbonate, halide-chalcogenide glasses, titania-doped glass, titania-doped plastics, zirconia-doped glass, zirconia-doped plastics, alkaline metal oxide-doped glass, alkaline metal oxide-doped plastics, barium oxide-doped glass, barium-doped plastics, zinc oxide-doped glass, and zinc oxide-doped plastics. In certain examples, the dimensions of the substrate may vary depending on the desired efficiency, overall size of the concentrator and the like. In particular, the substrate may be thick enough such that a sufficient amount of light may be trapped, e.g., 70-80% or more of the quanta of radiation (i.e., 70-80% of the incident photons). In certain examples, the thickness of the substrate may vary from about 1 mm to about 4 mm, e.g., about 1.5 mm to about 3 mm. The overall length and width of the substrate may vary depending on its intended use, and in certain examples, the substrate may be about 10 cm to about 300 cm wide by about 10 cm to about 300 cm long. The exact shape of the substrate may also vary depending on its intended use environment. In some examples, the substrate may be planar or generally planar, whereas in other examples, the substrate may be non-planar. In certain examples, opposite surfaces of the substrate may be substantially parallel, whereas in other examples opposite surfaces may be diverging or converging. For example, the top and bottom surfaces may each be sloped such that the width of the substrate at one end is less than the width of the substrate at an opposite end.

In accordance with certain examples, the solar concentrators disclosed herein may be produced using a high refractive index material. The term “high refractive index” refers to a material having a refractive index of at least 1.7. By increasing the refractive index of the substrate, the light trapping efficiency of the solar concentrator may be increased. Illustrative high refractive index materials suitable for use in the solar concentrators disclosed herein include, but are not limited to, high index glasses such as lead-doped glass, aluminum oxide, halide-chalcogenide glasses, titania-doped glass, zirconia-doped glass, alkaline metal oxide-doped glass, barium oxide-doped glass, zinc oxide-doped glass, and other materials such as, for example, lead-doped plastics, barium-doped plastics, alkaline metal oxide-doped plastics, titania-doped plastics, zirconia-doped plastics, and zinc oxide-doped plastics . In some examples any material whose light trapping efficiency is at least 80% of the quanta of radiation or more may be used as a high refractive index substrate.

In accordance with certain examples, in a typical LSC not all of the emitted photons will be confined in the substrate. For a simple system that include three layers, the trapping efficiency η_{Trap} of the photons in a waveguide may be expressed as

$${η}_{Trap} = \sqrt{1 - \frac{{η}_{cladding}^{2}}{{η}_{core}^{2}}}$$

where η_{cladding} and η_{core} are the refractive indices of the cladding and core, respectively. For a simple air-clad glass waveguide, with core and cladding refractive indices of 1.5 and 1, respectively, about 75% of the re-emitted photons will be trapped. Certain embodiments disclosed herein are configured to increase the number of trapped photons and to provide a more efficient solar concentrator.

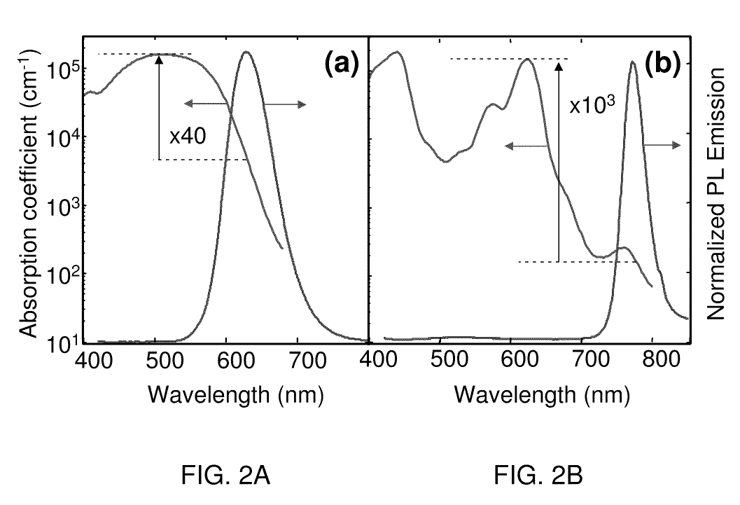

For a typical chromophore, the ratio of self absorption to the chromophore's peak absorption is desirably on the order of the concentration factor G. For example, for a 2 mm thick waveguide that is 1 meter wide, the concentration factor G is 500. The self-absorption is desirably less than 1/5000th of the peak absorption of the chromophore to have significant radiation reaching the edge. For example, the classic laser dye DCM (4-dicyanomethylene-2-methyl-6-(p-(dimethylamino)styryl)-4H-pyran), which was preferred by Batchelder et al. (Batchelder et al., Applied Optics, 18(18), 3090 (1979) has a normalized self absorption of approximately 5%, which limits the concentration factor to G of about 2. In contrast, certain chromophores used herein provide significant advantages when used in LSC's. Two examples of such chromophores are shown in FIGS. 2A and 2B. Referring to FIG. 2A, absorption and emission spectra from DCTJB (4-(dicyanomethylene-2-t-butyl-6(1,1,7,7-tetramethyljulolidyl-9-enyl)-4H-pyran) are shown. The absorption ratio between absorption peak and emission peak for DCTJB is about 50. Referring to FIG. 2B, absorption and emission spectra for Pt[tptb] (platinum tetraphenyltetrabenzoporphyrin) are shown. The ratio of the absorption coefficient peak at the peak absorption wavelength to the absorption coefficient at the peak emission wavelength for Pt[tptb] is several hundred or more. In some examples, materials that provide a ratio of the absorption coefficient peak at the peak absorption wavelength to the absorption coefficient at the peak emission wavelength of 40 or more may be used in the solar concentrators disclosed herein.

In certain examples, first and second chromophores may be disposed on or in a substrate and may be selected to exploit Förster near field energy transfer. Förster near field energy transfer couples the transition dipoles of neighboring molecules and may be exploited to couple one chromophore with a short wavelength absorption to a second chromophore with a longer wavelength absorption. For example, the concentrator may be configured with closely spaced chromophores. As used herein, the term “closely-spaced” refers to positioning or arranging the chromophores adjacent to or sufficiently close to each other such that Förster near field energy transfer may occur from one of the chromophores to the other chromophore. Such transfer of energy generally occurs without emission of a photon and results in an energy shift between absorption and emission.

In certain examples, at least first and second closely spaced chromophores may be disposed on or in the substrate in a manner to receive optical radiation. The first chromophore may be effective to absorb at least one wavelength of the optical radiation and may be arranged to transfer energy by Förster energy transfer to the second chromophore. The second chromophore may be effective to emit the transferred energy at a wavelength that is red-shifted from the wavelength absorbed by the first chromophore. The use of two chromophores as described above may improve the overall efficiency of the solar concentrator by reducing self-absorptions. In one illustration, the first chromophore may be tris-(8-hydroxylquinoline) aluminum (AlQ3) or rubrene, or both, and the second chromophore, which emits light, may be DCM. Both of tris-(8-hydroxylquinoline) aluminum or rubrene are fluorescent at high concentrations and have suitable electronic properties that permit energy transfer to DCM. In some examples, the chromophore may be a perylene or terrylene diimide molecule or a molecule having at least one perylene or terrylene diimide unit in it, e.g., a derivatized perylene or terrylene diimide chromophore.

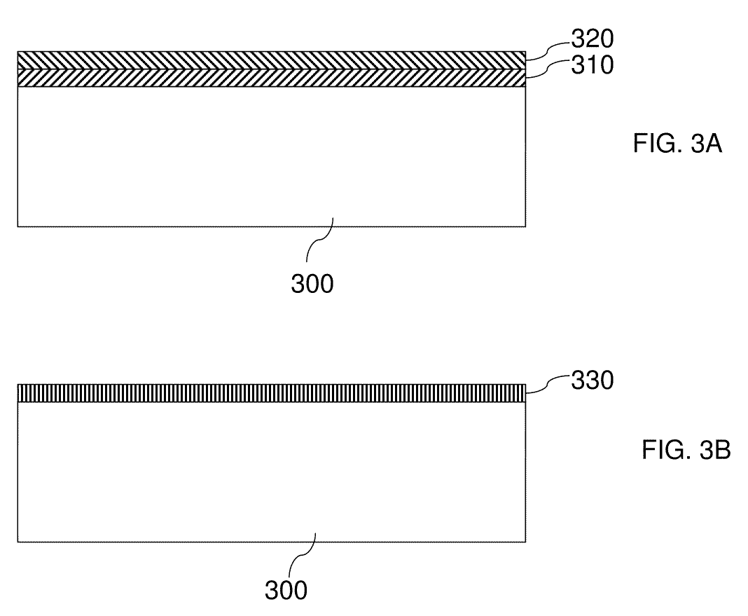

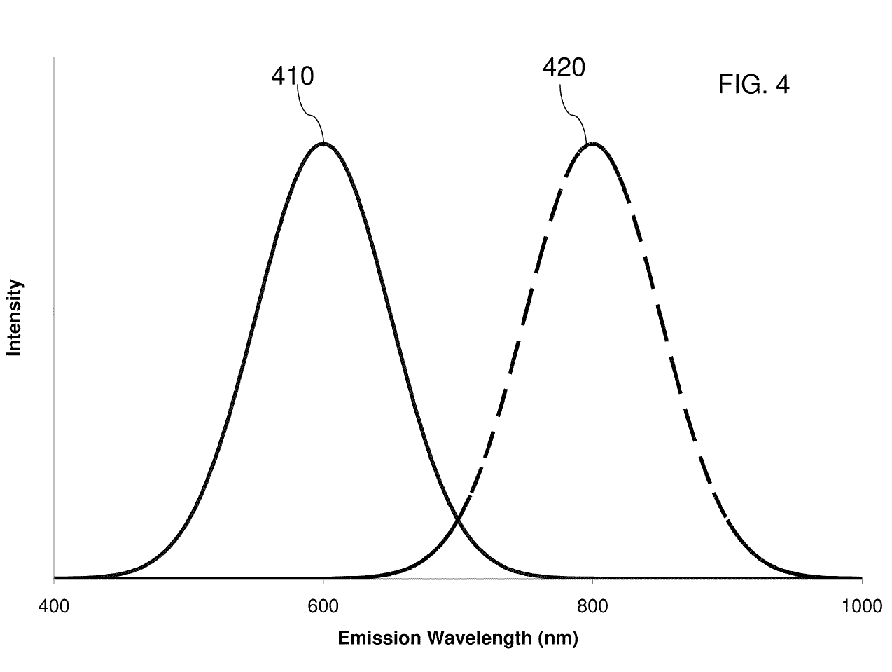

In certain examples, to take advantage of the Förster energy transfer, which is typically a short range interaction occurring over 3-4 nm, the chromophores may be disposed in one or more thin films on a substrate. For example and referring to FIG. 3A, a thin film of a first chromophore 310 may be disposed on a substrate 300. A thin film of a second chromophore 320 may be disposed on the first chromophore 310. In an alternative configuration as shown in FIG. 3B, the chromophores may be mixed together and disposed simultaneously on the substrate 300 to provide a thin film 330 or may be co-evaporated on the substrate 300 to provide a thin film 330. The exact thickness of the thin film may vary, and in certain examples, the film is about 0.5 microns to about 20 microns, more particularly about 1 micron to about 10 microns. In some examples, the Förster energy transfer ensures red-shifting of the emission. Such red-shifting provides the advantage of reducing the emission spectrum overlap with the absorption spectrum, which could decrease the overall efficiency of the solar concentrator. For example and referring to FIG. 4, the Förster energy transfer can result in shifting of the light emission to a higher wavelength 420 as compared to the wavelength emission 410 in the absence of Förster energy transfer. Such shifting reduces the overlap between the absorption and emission spectra thus reducing the likelihood of reabsorption.

In accordance with certain examples, to favor Förster energy transfer, it may be desirable to incorporate different amounts of the various chromophores into the solar concentrators. For example, it may be desirable to use substantially lower amounts of the chromophore that emits the light and higher amounts of the chromophore that transfers the energy by Förster energy transfer. In some examples, at least five times more of the chromophore absorbing the optical radiation, e.g., the solar radiation, is present as compared to the amount of light emitting chromophore that is present. In other examples, at least ten times more of the chromophore absorbing the optical radiation is present as compared to the amount of light emitting chromophore that is present. Suitable ratios of light absorbing chromophores to light emitting chromophores will be readily selected by the person of ordinary skill in the art, given the benefit of this disclosure.

In accordance with certain examples, it may be desirable to use multiple different chromophores to absorb the optical radiation and a single terminal chromophore to emit light to the PV cell. The terminal chromophore may be disposed adjacent to or near the PV cell such that light emission occurs in proximity to the PV cell. For example, two or more chromophores that absorb light at different wavelengths may be disposed on or in the substrate. Each of the chromophores may be configured such that they transfer energy to one or more terminal chromophores that emit light, e.g., the chromophores that absorb light do not substantially emit light by fluorescence or other radiative transition pathways. The terminal chromophore may emit light to a PV cell optically coupled to the solar concentrator. In some examples, the terminal chromophore may be selected such that its light emission is red-shifted from the absorption spectrum of the other chromophores to reduce the likelihood of re-absorption events that may lower the efficiency of the device.

In certain examples, the chromophores may be disposed on the substrate as shown in FIGS. 3A and 3B, whereas in other examples, the chromophores may be in the substrate itself, e.g., embedded, impregnated, injected into, co-fabricated with or the like. For example, the chromophores may be dispersed within the substrate body or the substrate itself may be produced by disposing various thin films onto each other with the chromophores disposed in a thin film between two or more layers of the thin film substrate. The overall thin film stack may make up the entire solar concentrator device.

In accordance with certain examples, the solar concentrators disclosed herein may be configured such that light emission to the PV cell occurs by phosphorescence. As a chromophore absorbs optical radiation, an electron is promoted from the highest occupied molecular orbital (HOMO) to the lowest unoccupied molecular orbital (LUMO). The excited state may take several forms or spin states including singlet states and triplet states. For molecules with strong fluorescence, the singlet state has a strongly allowed radiative transition to the ground state. For molecules that emit light by phosphorescence, the radiative transition from triplet excited state to singlet ground state is spin forbidden and is also lower in energy than decay from a singlet state. Thus, the emission wavelength of phosphors is Stokes shifted (shifted to longer wavelengths) and also occurs for longer periods due to the spin forbidden nature of the transition.

In accordance with certain examples, the compound disposed on or in the waveguide may be an organometallic compound. In some examples, the organometallic compound may include a transition metal bonded, chelated or coordinated to one or more ligands. Such ligands may include groups having lone pair electrons that may be used to coordinate the metal center. The transition metal may be charged or uncharged and the overall complex may adopt many different geometries including, for example, linear, angular, trigonal planar, square planar, tetrahedral, octahedral, trigonal pyramidal, square pyramidyl, trigonal bipyramidal, rhombic and the like.

In certain examples, the compound disposed on or in the substrate may be a porphyrin compound. In some examples, the porphyrin compound has a general formula as shown in formula (I) below.

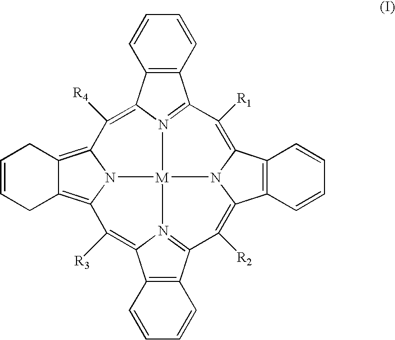

In some examples, each of R₁, R₂, R₃ and R₄ of formula (I) may independently be selected from a saturated or unsaturated hydrocarbon (e.g., a linear, branched or cyclic, substituted or unsubstituted hydrocarbon) having between one and ten carbon atoms, more particular having between one and six carbon atoms, e.g., between four and six carbon atoms. In certain examples, each of R₁, R₂, R₃ and R₄ may independently be selected from one or more of alkyl, alkenyl, alkynyl, aryl, aralkyl, naphthyl and other substituted or unsubstituted hydrocarbons having one to ten carbon atoms. In some examples, at least one of R₁, R₂, R₃ and R₄ may include at least one non-carbon atom, e.g., may include at least one oxygen atom, one sulfur atom, one nitrogen atom or a halogen atom. In some examples at least one of R₁, R₂, R₃ and R₄ may be a heterocyclic group. In one embodiment, each of R₁, R₂, R₃ and R₄ is a substituted or unsubstituted aryl group. In some examples, each of R₁, R₂, R₃ and R₄ is benzyl (C₆H₅) as shown below in formula (II).

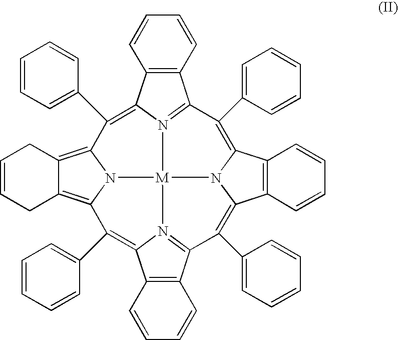

In formulas I and II, M may be any metal. In some examples, M may be a transition metal such that spin-orbital coupling is promoted to favor phosphorescence emission over fluorescence emission. In some examples, M may be a “heavy atom” having a atomic weight of at least about 100, more particularly at least about 190, e.g., an atomic weight of 200 or greater. In certain embodiments, M may be iridium, platinum, palladium, osmium, rhenium, hafnium, thorium, ruthenium and metals having similar electronic properties. Additional metals and groups for use in porphyrin compounds for use in a solar concentrator will be readily selected by the person of ordinary skill in the art, given the benefit of this disclosure.

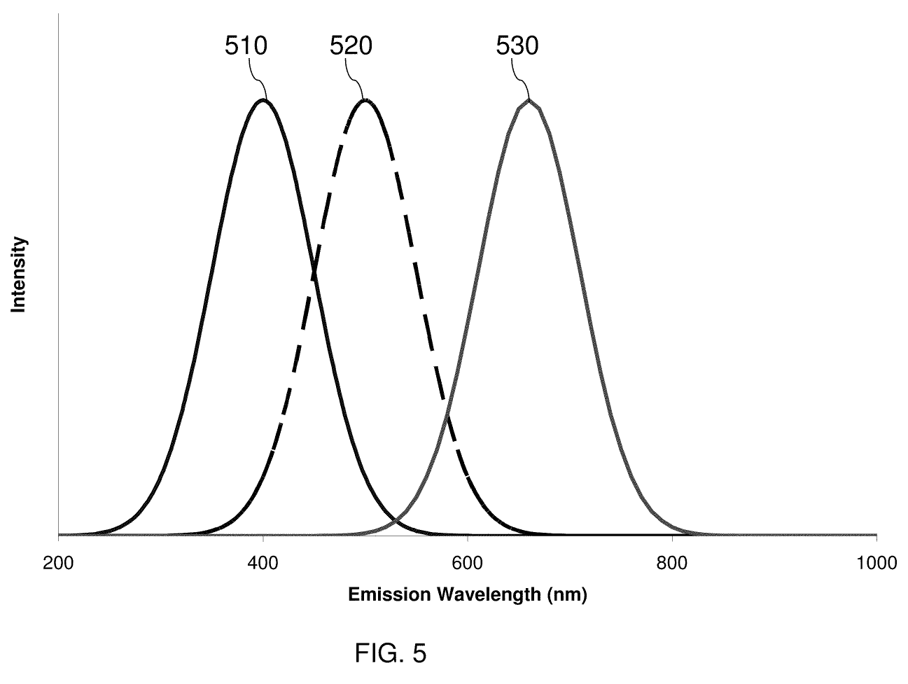

In accordance with certain examples, a composition comprising a material effective to absorb optical radiation within a first wavelength range and to emit the absorbed optical radiation by phosphorescence within a second wavelength range that is red-shifted from the first wavelength range is provided. In certain examples, the first and second wavelength ranges do not substantially overlap in wavelength. As used herein, “do not substantially overlap” refers to overlap by less than about 50 nm, more particularly less than about 20 nm, e.g., less than about 15 nm. By selecting a composition that has reduced or substantially no overlap between the absorption wavelength spectrum and the emission wavelength spectrum, the overall efficiency of the LSC may be increased by, for example, reducing re-absorption. Selection and design of phosphors can result in shifting of the emission wavelength to higher wavelengths and thus reduce or eliminate spectral overlap. An example of this feature is shown in FIG. 5. The absorption wavelength spectrum 510 is shown as being blue-shifted (anti-Stokes shift) from the phosphorescence emission wavelength spectrum 530. In contrast, there may be substantial overlap between the absorption wavelength spectrum and the fluorescence wavelength spectrum 520. By selecting suitable compositions that decay primarily by phosphorescence emission, the spectral overlap between the absorption and light emission may be substantially reduced or eliminated.

In accordance with certain examples, the compositions for use in the LSC's disclosed herein may include one or more agents designed to red-shift the emission. Such red-shifting agents may be integral to the composition or may be added or doped into the composition in an effective amount to shift the light emission to longer wavelengths. Such red-shifting agents include, but are not limited to, heavy metals, chelators, compositions having one or more conjugated ring systems, matrix materials to trap the chromophore in and the like. In some examples, one or more steric groups may be added to limit or slow movement of the chromophore or to interact with, or affect, the pi-orbital systems of the chromophore.

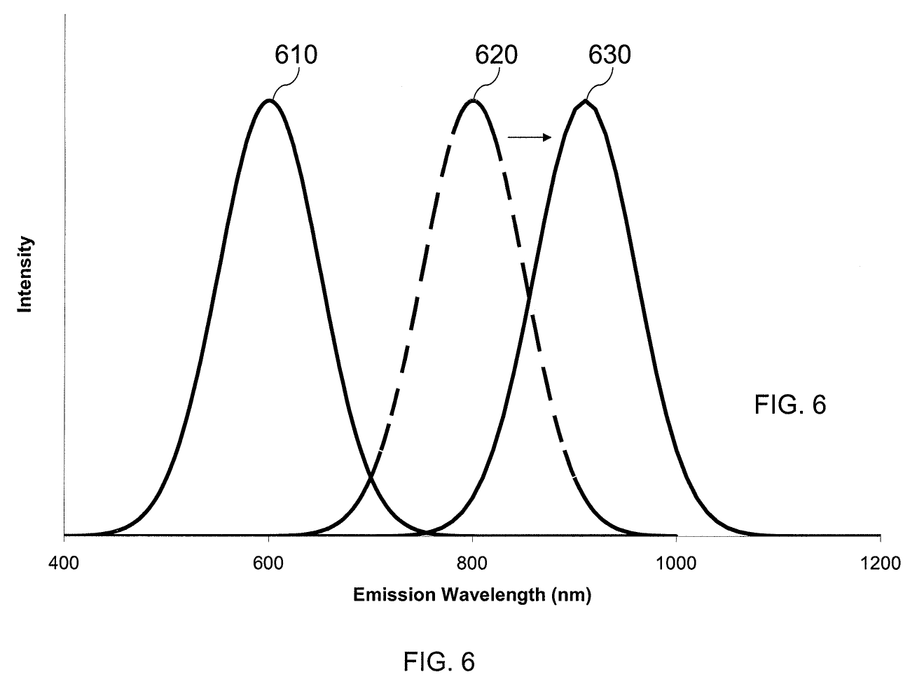

In accordance with certain examples, the solar concentrator may include a porphyrin compound and a red-shifting agent. In some examples, the red-shifting agent may be effective to shift the wavelength of the chromophore, e.g., a metalloporphyrin compound, to a longer emission wavelength than that observed in the absence of the red-shifting agent. An illustration of this red-shifting is shown in FIG. 6. A light absorption spectrum 610 is shown as being blue-shifted in comparison to a light emission spectrum 620. By doping the waveguide with a red-shifting agent, or including or otherwise depositing or co-depositing a red-shifting agent with the chromophore, the light emission spectrum may be red-shifted to a higher wavelength, as shown by light emission spectrum 630.

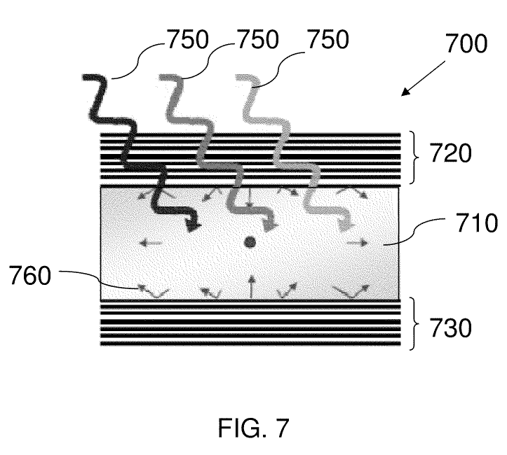

In accordance with certain examples, the devices disclosed herein may include one or more wavelength selective mirrors disposed thereon. In some examples, the wavelength selective mirrors may serve to increase the efficiency further by confining reflections within the substrate. For example, as solar radiation is incident on the solar concentrator some of the incident light may be reflected away from the substrate resulting in lower capturing of the light. By including at least one wavelength selective mirror on a surface of the solar concentrator, the light may be retained internally and provided to one or more PV cells coupled to the solar concentrator. An illustration of this configuration for a solar concentrator is shown in FIG. 7. The device 700 comprises a substrate 710 comprising one or more chromophores disposed on or in the substrate 710, as described herein. The device 710 also comprises a first reflective mirror 720 on a first surface and a second reflective mirror 730 on an opposite surface. The first selective mirror 720 may be configured such that light of certain wavelengths, shown as arrows 750, is permitted to be passed by the first selective mirror 720 into the substrate 710. The first selective mirror 720 may be designed such that reflected light, such as reflected light 760, is retained with the substrate, e.g., the reflected light is reflected back into the substrate by the first selective mirror 720. Similarly, the second selective mirror 730 may be designed such that it reflects incident light back into the substrate 710. The use of reflective mirrors permits trapping of the light within the substrate to increase the overall efficiency of the device 700.

In certain examples, the wavelength selective mirrors may comprise alternating thin films of, for example, one or more dielectric materials to provide a thin film stack than is operative as a wavelength selective mirror. In some examples, the thin films stacks are produced by disposing thin film layers having different dielectric constants on a substrate surface. The exact number of thin films in the thin film stack may vary depending, for example, on the materials used, the desired transmission and reflection wavelengths and the like. In some examples, the thin film stack may include from about 6 thin film layers to about 48 thin film layers, more particularly about 12 thin film layers to about 24 thin film layers, e.g., about 16 thin film layers to about 12 thin film layers. The exact materials used to produce the thin film layers may also vary depending on the desired number of thin films layers, the desired transmission and reflection wavelengths and the like. In some examples, a first thin film may be produced using, for example, a material such as polystyrene, cryolite and the like. A second thin film may be disposed on the first thin film using, for example, metals such as tellerium, zinc selenide and the like. In some examples, each of the thin films may have a thickness that varies from about 20 nanometers to about 100 nanometers, more particularly, about 30 nanometers to about 80 nanometers, e.g., about 50 nanometers. One advantage of using thin films is that mirrors comprised of thin films may permit retention of light at all angles of incidence and polarizations to further increase the light trapping efficiency of the solar concentrator. Solar concentrators having such thin film mirrors can receive more light thus increasing the efficiency of the solar cell device.

In accordance with certain examples, to further decrease re-absorption of the light, it may be desirable to alter the local environment of the chromophores. The local environment can affect the electronic properties of the chromophores such that chromophores having the same composition but in different local environments may have different optical properties, e.g., different emission wavelengths. In certain examples, the environment of the chromophore may be altered or tuned such that the ground state or neutral chromophore (not excited by light) behaves differently than the excited molecule. For example, the environment of the chromophore may include, or be doped with, another molecule that is charged or has a high degree of charge separation, e.g., a high dipole moment. As the excited state of many chromophores exhibits a large dipole moment, if the excited chromophore has spatial or rotational degrees of freedom, it can move or rotate to decrease the energy of the system which generally results in red-shifting of the emission wavelength. As discussed elsewhere herein, red-shifting of the emission spectrum can result in a decrease in the absorption and emission spectra, which decreases the likelihood of re-absorption and increases the overall efficiency of the solar concentrator.

In certain examples, the local environment of the chromophore may be altered by adding or doping a molecule into the substrate and/or co-depositing the molecule with the chromophore. Such doping or co-depositing can result in solid state solvation of the chromophore and alter the electronic properties of the excited state to alter the emission wavelength. In some examples, an effective amount of the dopant may be added to the molecule such that the emission wavelength is red-shifted by about 5 nm to about 50 nm, more particularly about 10 nm to about 40 nm, e.g., about 20 nm to about 30 nm. The exact nature of the composition used as a dopant may vary and, in particular, molecules having a dipole moment of at least 2 debyes, more particularly at least 3 debyes, e.g., about 5 debyes or more may be used. In some examples, the dopant may provide a polar matrix that alters the optical properties of the chromophore.

In certain examples, the concentration of the dopant may be from about 0.5% to about 99%, more particular about 1% to about 90%, based on the weight of the host material. For example, if 10% by weight of dopant is used, then when the entire mass of the film is considered, 10% of its mass is from the dopant. The dopant may be any material, other than the emitting chromophore, that may alter the local environment of the emitting chromophore. For example, the host material itself may be considered a dopant if it alters the local environment of the emitting chromophore. In some examples, the dopant may be one or more materials including, but not limited to, tris(8-hydroxyquinoline), laser dyes such as, for example, 2-methyl-6-[2-(2,3,6,7-tetrahydro-1H, 5H-benzo[i,j]quinolizin-9-yl)-ethenyl]-4H-pyran-4-ylidene]propane dinitrile (DCM2), camphoric anhydride, Indandione-1,3 pyridinium betaine compounds, and azobenzene chromophores. Additional dopants and concentrations to alter the local environment of a chromophore will be readily selected by the person of ordinary skill in the art, given the benefit of this disclosure.

In some examples, the dopant itself may be present in an amount that permits transfer of energy, and optionally emission of light by the dopant, but not at so high a concentration or amount that substantial direct light absorption by the dopant itself occurs. For example, it may be desirable to select suitable concentrations of the materials such that light absorption by one of the species dominates. In some examples where a dopant is present, the dopant may be present at an amount such that direct light absorption by the dopant is 15% or less, e.g., 10% or less or 0-5%, of the total photons incident on the device. It will be within the ability of the person of ordinary skill in the art, given the benefit of this disclosure, to select suitable amounts of the materials in the LSC's disclosed herein such that one or more desired species preferentially absorbs light and one or more desired species preferentially emits light.

In accordance with certain examples, the efficiency of photon trapping by the solar concentrator may depend, at least in part, on the angle or orientation of the emitting chromophore. Chromophores oriented to absorb maximally may have a low trapping efficiency, whereas chromophores oriented to trap efficiently may absorb weakly. By controlling the orientation of the chromophores, both light trapping efficiency and light absorption may be increased. In particular, the orientation of the terminal chromophore, e.g., the light emitting chromophore may be selected such that light trapping efficiency is maximized. In embodiments where energy transfer is used to deliver energy to the terminal chromophore, the weak light absorption by the terminal chromophore is not relevant. The absorbing chromophores may be either randomly oriented or oriented to jointly optimize light absorption and energy transfer efficiency to the terminal chromophore. It will be within the ability of the person of ordinary skill in the art to design solar concentrators that include selectively oriented chromophores. In some examples, a first chromophore may be oriented at an angle to increase absorption of light incident on the substrate. This result may occur, for example, if the transition dipole of the first chromophore was oriented perpendicular to the incident light rays and/or parallel to the guiding direction. For example, by orienting the first chromophore at a selected angle the amount of light absorbed may be increased by 10% to about 50% or more as compared to a random orientation. In other examples, the second chromophore may be oriented at an angle to increase the light-trapping efficiency. This result may occur, for example, if the transition dipole of the second chromophore was oriented parallel to the incident light rays and/or perpendicular to the guiding direction. For example, by orienting the second chromophore at a selected angle the light-trapping efficiency may be increased by 10% to about 50% or more compared to a random orientation.

In certain examples, the solar concentrator of the devices disclosed herein may include a substrate comprising at least first and second closely spaced chromophores disposed on or in the substrate in a manner to receive at least some optical radiation, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In other embodiments, the solar concentrator of the devices disclosed herein may include a substrate comprising at least first and second closely spaced chromophores disposed on or in the substrate in a manner to receive optical radiation, the first chromophore effective to absorb at least some optical radiation and to transfer at least some energy to the second chromophore, the second chromophore effective to emit at least some of the transferred energy at a wavelength that is red-shifted from a wavelength of optical radiation absorbed by the first chromophore, in which the first chromophore is present at a concentration at least ten times greater than the concentration of the second chromophore. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In additional embodiments, the solar concentrator of the devices disclosed herein may include a substrate comprising a plurality of chromophores disposed on or in the substrate in a manner to receive optical radiation, the plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In some examples, the solar concentrator of the devices disclosed herein may include a substrate comprising a film disposed on the substrate in a manner to receive at least some optical radiation, the film comprising at least a first chromophore and a second chromophore, the first chromophore effective to absorb at least one wavelength of at least some of the optical radiation and further effective to transfer at least some of the energy by Förster energy transfer to the second chromophore, the second chromophore effective to emit at least some of the transferred energy at a wavelength that is red-shifted from the wavelength absorbed by the first chromophore. In some examples, the solar concentrator may include one or more wavelength selective mirrors on a surface. In other examples, the first chromophore may be disposed in a polar matrix. The solar concentrator may be optically coupled to the PV cell to provide light to the PV cell.

In certain embodiments, the solar concentrator of the devices disclosed herein may include a substrate comprising a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In some embodiments, the solar concentrator of the devices disclosed herein may include a substrate comprising a film disposed on the substrate in a manner to receive at least some optical radiation, the film comprising at least a first chromophore and a second chromophore, the first chromophore effective to absorb at least some optical radiation and transfer at least some energy to the second chromophore, the second chromophore effective to emit at least some of the transferred energy at a wavelength that is red-shifted from a wavelength of optical radiation absorbed by the first chromophore. In certain examples, the first chromophore is present in the film at a concentration at least ten times greater than the concentration of the second chromophore in the film. In some examples, the solar concentrator may include one or more wavelength selective mirrors on a surface. In other examples, the first chromophore may be disposed in a polar matrix. The solar concentrator may be optically coupled to the PV cell to provide light to the PV cell.

In certain examples, the solar concentrator of the devices disclosed herein may include a substrate comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, the material may be disposed in a polar matrix. The solar concentrator may be optically coupled to the PV cell to provide light to the PV cell.

In some embodiments, the solar concentrator of the devices disclosed herein may include a substrate comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to higher wavelengths such that the first and second wavelength ranges do not substantially overlap in wavelength. In some examples, the solar concentrator may include one or more wavelength selective mirrors on a surface. In other examples, the material may be disposed in a polar matrix. The solar concentrator may be optically coupled to the PV cell to provide light to the PV cell.

In other examples, the solar concentrator of the devices disclosed herein may include a substrate comprising a composition disposed on or in the substrate in a manner to absorb at least some optical radiation, the composition comprising at least one porphyrin compound. In some examples, the solar concentrator may include one or more wavelength selective mirrors on a surface. In other examples, the porphyrin compound may be disposed in a polar matrix. The solar concentrator may be optically coupled to the PV cell to provide light to the PV cell.

In additional embodiments, the solar concentrator of the devices disclosed herein may include a substrate comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, the porphyrin compound may be disposed in a polar matrix. The solar concentrator may be optically coupled to the PV cell to provide light to the PV cell.

In certain embodiments, the solar concentrator of the devices disclosed herein may include a substrate comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. The solar concentrator may be optically coupled to the PV cell to provide light to the PV cell.

In some embodiments, the solar concentrator of the devices disclosed herein may include a substrate comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the porphyrin compound to shift the second wavelength range to a higher wavelength range such that the first and second wavelength ranges do not substantially overlap in wavelength. In some examples, the solar concentrator may include one or more wavelength selective mirrors on a surface. In other examples, the porphyrin compound may be disposed in a polar matrix. The solar concentrator may be optically coupled to the PV cell to provide light to the PV cell.

In certain examples, the solar concentrator of the devices disclosed herein may include a substrate comprising a composition disposed on or in the substrate in a manner to absorb at least some optical radiation, the composition comprising at least one organometallic compound. In some examples, the solar concentrator may include one or more wavelength selective mirrors on a surface. In other examples, the organometallic compound may be disposed in a polar matrix. The solar concentrator may be optically coupled to the PV cell to provide light to the PV cell.

In some examples, the solar concentrator of the devices disclosed herein may include a substrate comprising a composition disposed on or in the substrate in a manner to absorb at least some optical radiation, the composition comprising at least one organometallic compound effective to absorb the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, the organometallic compound may be disposed in a polar matrix. The solar concentrator may be optically coupled to the PV cell to provide light to the PV cell.

In certain embodiments, the solar concentrator of the devices disclosed herein may include a substrate comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In some examples, the solar concentrator may include one or more wavelength selective mirrors on a surface. In other examples, the organometallic compound may be disposed in a polar matrix. The solar concentrator may be optically coupled to the PV cell to provide light to the PV cell.

In some embodiments, the solar concentrator of the devices disclosed herein may include a substrate comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the organometallic compound to shift the second wavelength range to a higher wavelength range such that the first and second wavelength ranges do not substantially overlap in wavelength. In some examples, the solar concentrator may include one or more wavelength selective mirrors on a surface. In other examples, the organometallic compound may be disposed in a polar matrix. The solar concentrator may be optically coupled to the PV cell to provide light to the PV cell.

In certain examples, the solar concentrator of the devices disclosed herein may include a substrate having a refractive index of greater than or equal to 1.7 and comprising a chromophore disposed on or in the substrate and effective to absorb optical radiation. In some examples, the solar concentrator may include one or more wavelength selective mirrors on a surface. In other examples, the chromophore may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising at least first and second closely spaced chromophores disposed on or in the substrate in a manner to receive at least some optical radiation, the first chromophore effective to absorb at least one wavelength of at least some of the optical radiation and arranged to transfer at least some energy by Förster energy transfer to the second chromophore, the second chromophore effective to emit at least some of the transferred energy at a wavelength that is red-shifted from the wavelength absorbed by the first chromophore. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In certain embodiments, the solar concentrator of the devices disclosed herein may include a substrate having a refractive index of greater than or equal to 1.7 and comprising a plurality of chromophores disposed on or in the substrate in a manner to receive at least some optical radiation, the plurality of chromophores each effective to absorb at least one wavelength of at least some of the optical radiation without substantial light emission of the absorbed optical radiation. In some examples, the film further comprises a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising at least first and second closely spaced chromophores disposed on or in the substrate in a manner to receive at least some optical radiation, the first chromophore effective to absorb at least some optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present at a concentration at least ten times greater than the concentration of the second chromophore. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In certain embodiments, the solar concentrator of the devices disclosed herein may include a substrate having a refractive index of at least about 1.7 and comprising a film disposed on the substrate in a manner to receive optical radiation, the film comprising at least a first chromophore and a second chromophore, the first chromophore effective to absorb at least one wavelength of at least some of the optical radiation and arranged to transfer at least some energy by Förster energy transfer to the second chromophore, the second chromophore effective to emit at least some of the transferred energy at a wavelength that is red-shifted from the wavelength absorbed by the first chromophore. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In certain examples, the solar concentrator of the devices disclosed herein may include a substrate having a refractive index of greater than or equal to 1.7 and comprising a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore effective to emit at least some of the received energy at a wavelength that is red-shifted from the at least one wavelength absorbed by the plurality of chromophores. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising a film disposed on the substrate in a manner to receive at least some optical radiation, the film comprising at least a first chromophore and a second chromophore, the first chromophore effective to absorb at least some optical radiation and transfer at least some of the energy to the second chromophore, the second chromophore effective to emit at least some of the transferred energy at a wavelength that is red-shifted from a wavelength of optical radiation absorbed by the first chromophore, in which the first chromophore is present in the film in a concentration at least ten times greater than the concentration of the second chromophore in the film. In some examples, the solar concentrator may include one or more wavelength selective mirrors on a surface. In other examples, the chromophore(s) may be disposed in a polar matrix. The solar concentrator may be optically coupled to the PV cell to provide light to the PV cell.

In certain embodiments, the solar concentrator of the devices disclosed herein may include a substrate having a refractive index of greater than or equal to 1.7 and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, the material may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In some examples, the material may include one or more wavelength selective mirrors on a surface. In other examples, the chromophore(s) may be disposed in a polar matrix. The solar concentrator may be optically coupled to the PV cell to provide light to the PV cell.

In certain embodiments, the solar concentrator of the devices disclosed herein may include a substrate having a refractive index of greater than or equal to 1.7 and comprising a composition disposed on or in the substrate in a manner to absorb at least some optical radiation, the composition comprising at least one porphyrin compound. In some examples, the solar concentrator may include one or more wavelength selective mirrors on a surface. In other examples, the porphyrin compound may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, the porphyrin compound may be disposed in a polar matrix. The solar concentrator may be optically coupled to the PV cell to provide light to the PV cell.

In additional examples, the solar concentrator of the devices disclosed herein may include a substrate having a refractive index of greater than or equal to 1.7 and comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In some examples, the solar concentrator may include one or more wavelength selective mirrors on a surface. In other examples, the porphyrin compound may be disposed in a polar matrix. The solar concentrator may be optically coupled to the PV cell to provide light to the PV cell.

In certain embodiments, the solar concentrator of the devices disclosed herein may include a substrate having a refractive index of greater than or equal to 1.7 and comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the porphyrin compound to shift the second wavelength range to a higher wavelength range such that the first and second wavelength ranges do not substantially overlap in wavelength. In some examples, the solar concentrator may include one or more wavelength selective mirrors on a surface. In other examples, the porphyrin compound may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising a composition disposed on or in the substrate in a manner to absorb at least some optical radiation, the composition comprising at least one organometallic compound. In some examples, the solar concentrator may include one or more wavelength selective mirrors on a surface. In other examples, the organometallic compound may be disposed in a polar matrix. The solar concentrator may be optically coupled to the PV cell to provide light to the PV cell.

In certain examples, the solar concentrator of the devices disclosed herein may include a substrate having a refractive index of greater than or equal to 1.7 and a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, the organometallic compound may be disposed in a polar matrix. The solar concentrator may be optically coupled to the PV cell to provide light to the PV cell.

In some embodiments, the solar concentrator of the devices disclosed herein may include a substrate having a refractive index of greater than or equal to 1.7 and comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength.

In some examples, the solar concentrator may include one or more wavelength selective mirrors on a surface. In other examples, the organometallic compound may be disposed in a polar matrix. The solar concentrator may be optically coupled to the PV cell to provide light to the PV cell.

In certain examples, the solar concentrator of the devices disclosed herein may include a substrate having a refractive index of greater than or equal to 1.7 and comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the organometallic compound to shift the second wavelength range to a higher wavelength range such that the first and second wavelength ranges do not substantially overlap in wavelength. In some examples, the solar concentrator may include one or more wavelength selective mirrors on a surface. In other examples, the organometallic compound may be disposed in a polar matrix. The solar concentrator may be optically coupled to the PV cell to provide light to the PV cell.

In some embodiments, the solar concentrator of the devices disclosed herein may include a substrate configured to trap at least 80% of the quanta of radiation incident on the substrate and a chromophore disposed on or in the substrate and effective to absorb at least some optical radiation and emit at least some of the absorbed optical radiation at a longer wavelength. In some examples, the solar concentrator may include one or more wavelength selective mirrors on a surface. In other examples, the chromophore may be disposed in a polar matrix. The solar concentrator may be optically coupled to the PV cell to provide light to the PV cell.

In certain embodiments, the solar concentrator of the devices disclosed herein may include a substrate configured to trap at least 80% of the quanta of radiation incident on the substrate and comprising at least first and second closely spaced chromophores disposed on or in the substrate in a manner to receive at least some optical radiation, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore. In some examples, the solar concentrator may include one or more wavelength selective mirrors on a surface. In other examples, the chromophore(s) may be disposed in a polar matrix. The solar concentrator may be optically coupled to a PV cell to provide light to the PV cell.

In some examples, the solar concentrator of the devices disclosed herein may include a substrate configured to trap at least 80% of the quanta of radiation incident on the substrate and comprising at least first and second closely spaced chromophores disposed on or in the substrate in a manner to receive at least some optical radiation, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present in a concentration at least ten times greater than the concentration of the second chromophore. In some examples, the solar concentrator may include one or more wavelength selective mirrors on a surface. In other examples, the chromophore(s) may be disposed in a polar matrix. The solar concentrator may be optically coupled to a PV cell to provide light to the PV cell.

In certain embodiments, the solar concentrator of the devices disclosed herein may include a substrate configured to trap at least 80% of the quanta of radiation incident on the substrate and comprising at least first and second closely spaced chromophores disposed on the substrate in a manner to receive at least some optical radiation, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present at a concentration at least ten times greater than the concentration of the second chromophore. In some examples, the solar concentrator may include one or more wavelength selective mirrors on a surface. In other examples, the chromophore(s) may be disposed in a polar matrix. The solar concentrator may be optically coupled to a PV cell to provide light to the PV cell.

In certain examples, the solar concentrator of the devices disclosed herein may include a substrate configured to trap at least 80% of the quanta of radiation incident on the substrate and comprising a film disposed on the substrate in a manner to receive at least some optical radiation, the film comprising at least a first chromophore and a second chromophore, the first chromophore effective to absorb at least one wavelength of at least some of the optical radiation and arranged to transfer at least some energy by Förster energy transfer to the second chromophore, the second chromophore effective to emit at least some of the transferred energy at a wavelength that is red-shifted from the wavelength absorbed by the first chromophore. In some examples, the solar concentrator may include one or more wavelength selective mirrors on a surface. In other examples, the chromophore(s) may be disposed in a polar matrix. The solar concentrator may be optically coupled to a PV cell to provide light to the PV cell.

In other examples, the solar concentrator of the devices disclosed herein may include a substrate configured to trap at least 80% of the quanta of radiation incident on the substrate and comprising a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In some examples, the solar concentrator may include one or more wavelength selective mirrors on a surface. In other examples, the chromophore(s) may be disposed in a polar matrix. The solar concentrator may be optically coupled to a PV cell to provide light to the PV cell.

In certain embodiments, the solar concentrator of the devices disclosed herein may include a substrate configured to trap at least 80% of the quanta of radiation incident on the substrate and comprising a film disposed on the substrate in a manner to receive at least some optical radiation, the film comprising at least a first chromophore and a second chromophore, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present in the film at a concentration at least ten times greater than the concentration of the second chromophore in the film. In some examples, the solar concentrator may include one or more wavelength selective mirrors on a surface. In other examples, the chromophore(s) may be disposed in a polar matrix. The solar concentrator may be optically coupled to a PV cell to provide light to the PV cell.

In some embodiments, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, the material may be disposed in a polar matrix. The solar concentrator may be optically coupled to a PV cell to provide light to the PV cell.

In additional examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to higher wavelengths such that the first and second wavelength ranges do not substantially overlap in wavelength. In some examples, the solar concentrator may include one or more wavelength selective mirrors on a surface. In other examples, the material may be disposed in a polar matrix. The solar concentrator may be optically coupled to a PV cell to provide light to the PV cell.

In some examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one porphyrin compound. In some examples, the solar concentrator may include one or more wavelength selective mirrors on a surface. In other examples, the porphyrin compound may be disposed in a polar matrix. The solar concentrator may be optically coupled to a PV cell to provide light to the PV cell.

In certain examples, the solar concentrator of the devices disclosed herein may include a substrate configured to trap at least 80% of the quanta of radiation incident on the substrate and a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, the porphyrin compound may be disposed in a polar matrix. The solar concentrator may be optically coupled to a PV cell to provide light to the PV cell.

In certain embodiments, the solar concentrator of the devices disclosed herein may include a substrate configured to trap at least 80% of the quanta of radiation emitted in the substrate and comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In some examples, the solar concentrator may include one or more wavelength selective mirrors on a surface. In other examples, the porphyrin compound may be disposed in a polar matrix. The solar concentrator may be optically coupled to a PV cell to provide light to the PV cell.

In some examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the porphyrin compound to shift the second wavelength range to a higher wavelength range such that the first and second wavelength ranges do not substantially overlap in wavelength. In some examples, the solar concentrator may include one or more wavelength selective mirrors on a surface. In other examples, the porphyrin compound may be disposed in a polar matrix. The solar concentrator may be optically coupled to a PV cell to provide light to the PV cell.

In other examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one organometallic compound. In some examples, the solar concentrator may include one or more wavelength selective mirrors on a surface. In other examples, the organometallic compound may be disposed in a polar matrix. The solar concentrator may be optically coupled to a PV cell to provide light to the PV cell.

In certain embodiments, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, the organometallic compound may be disposed in a polar matrix. The solar concentrator may be optically coupled to a PV cell to provide light to the PV cell.

In some embodiments, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to higher wavelengths such that the first and second wavelength ranges do not substantially overlap in wavelength. In some examples, the solar concentrator may include one or more wavelength selective mirrors on a surface. In other examples, the organometallic compound may be disposed in a polar matrix. The solar concentrator may be optically coupled to a PV cell to provide light to the PV cell.

In accordance with certain examples, the solar concentrators disclosed herein may be used with many different types of PV cells and PV cells having different efficiencies. By using the solar concentrators disclosed herein, the efficiency of each PV cell need not be the same. For example, it may be desirable to use a high efficiency PV cell without a concentrator and use a low efficiency PV cell with a concentrator to provide substantially the same efficiency for each of the PV cells. In addition, it may be desirable to selectively position the PV cells in an array to utilize the different efficiencies. Electrical power losses from heating increase with increasing current flowing in a module circuit. The current is minimized with a serial configuration. For this reason, the typical configuration of individual solar cells when connected in a module is in series. For cells connected in this way, it is desirable that each cell passes the same amount of current. Otherwise, PV cells with lower currents will limit the total current that can flow through the whole module limiting the power conversion efficiency. In a typical module, effort and cost is devoted to testing and sorting individual cells such that all cells to be put into a module are as close to identical in performance as possible. Also, they are typically all the same size. The light intensity reaching the edges of a luminescent solar concentrator (LSC) depends on position on the guide. Since the light intensity depends on position, the current passing through each solar cell should also depend on position. If identical PV cells are used (either in size or performance), the module power conversion efficiency will be limited by the cell receiving the least light and thus passing the least current.

In accordance with certain examples, the geometry of the PV cell may also be tailored or designed such that PV cells having different efficiencies may be used with one or more of the solar concentrators disclosed herein. For example, the amount of light reaching each of the collection edges depends, ay least in part, on waveguide geometry. For manufacturing simplicity and cost, many solar concentrators may be produced in rectangular or square configurations, but other geometries are possible. For a simple rectangular case, the light reaching the corners will be lower than those edges closest to the center as optical losses increase with the distance light travels in the waveguide. By adjusting the PV cell efficiency as a function of position, higher efficiency cells can be used in the edges near the corners and lower efficiency cells can be used in the edges near the solar concentrator center. Using this arrangement, the current flowing through each PV cell may be substantially equal and module efficiency is not limited by lower current PV cells. This arrangement permits for the use of cells of variable performance efficiencies instead of using the lower efficiency cells in less valuable lower efficiency modules.

In certain examples, the dimension of the PV cells may also be adjusted to provide similar efficiencies. For example, by adjusting the cell dimensions of identically efficient cells, similar current matching is possible. If all cell heights are identical (set, for example, by the edge thickness), then the cell lengths may be altered to accommodate the differing light intensities as a function of position. PV cells at the edges closest to the corners may be longer, and cells at the edges closest to the concentrator center may be shorter. The use of such variable size PV cells with the concentrators disclosed herein provides similar efficiencies to increase the overall efficiency of a solar cell array.

In accordance with certain examples, the various materials used in the concentrators disclosed herein, e.g., chromophores, red-shifting agents, thin films, etc., may be disposed using numerous different methods including, but not limited to, painting, brushing, spin coating, casting, molding, sputtering, vapor deposition (e.g., physical vapor deposition, chemical vapor deposition and the like), plasma enhanced vapor deposition, pulsed laser deposition and the like. In some examples, organic vapor phase deposition (OVPD) may be used to deposit at least one of the components of the solar concentrators disclosed herein. OVPD may be used, for example, to dispose or coat a waveguide with one or more chromophores, red-shifting agents, heavy metals or the like. In some examples, OVPD may be used to produce a solar concentrator by disposing a vapor phase of the chromophore on a substrate and optionally curing or heating the substrate. Illustrative devices for OVPD are commercially available, for example, from Aixtron (Germany). Suitable methods, parameters and devices for OVPD are described, for example in Baldo et al., Appl. Phys. Lett. 71(2), 3033-3035, 1997.

In accordance with certain examples, a high index epoxy or adhesive may be used to attach the solar concentrators disclosed herein to a PV cell. For example, solar cells may be produced using a high index adhesive or epoxy such that index mismatching may be avoided or substantially reduced. For example, to reduce the light coupling losses, it may be desirable to reduce optical reflections as light passes from the LSC into the PV cell. There may be an index mismatch between the waveguide and the solar cell, but this mismatch need not introduce large reflections if the solar cell is covered by an antireflection coating (most solar cells have them built into their structure). These antireflection coatings may be designed for light that is incident from air but can be redesigned for light that is incident from a solar concentrator. If the PV cells are attached to the LSC by an epoxy or an adhesive, the epoxy or adhesive may introduce unwanted reflections, and the thickness of the epoxy or adhesive may be difficult to control. By using epoxies which are index-matched to the waveguide, the antireflection coating of the solar cell may be designed for light incident from the waveguide and the exact thickness of the epoxy or adhesive is less important. Thus, by using an epoxy or adhesive whose refractive index is matched to the substrate or waveguide, the overall efficiency of a solar cell may be increased.

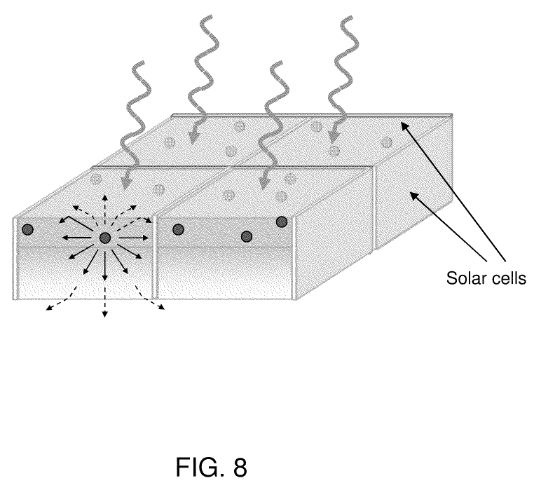

In accordance with certain examples, the PV cells may be embedded or otherwise integrated into the solar concentrators disclosed herein. For example, where the substrate is produced using one or more polymers, e.g., a plastic, it may be desirable to embed the PV cell into the waveguide rather than attach the PV cell at an edge of the waveguide. A configuration of such embedded PV cell is shown in FIG. 8. In embodiments where the concentrator is produced using a plastic, the PV cell can be embedded in the plastic melt when the liquid material is cast or injection molded. This process permits omission of any epoxy or adhesive joints to attach a PV cell to the solar concentrator. As the joints have been removed, the index matching to a substrate is not required, and the antireflection coating on the PV cell may be designed directly for light incident from the waveguide. In addition, in a solar concentrator that is limited in geometric optical gain by re-absorption losses, very large modules can be made with lower optical gains. For example, a chromophore may limit the concentration factor to 100, e.g., corresponding to waveguide dimensions of 80 cm×80 cm×2 mm. If a module with larger dimension is desired, e.g., 160 cm×160 cm×2 mm, four concentrators would be tiled in an array inside the module. This design constraint may be avoided by embedding the PV cells in a grid within the solar concentrator, so the module can be made larger without sacrificing performance due to chromophore re-absorption.

In accordance with certain examples, the solar cell devices disclosed herein may be arranged with other solar cell devices disclosed herein to provide an array of solar cells. For example, the system may comprise a plurality of photovoltaic cells constructed and arranged to receive optical radiation from the sun, wherein at least one of the plurality of photovoltaic cells is coupled to a solar concentrator as described herein. In particular, the solar concentrator of the system may be any one or more of the solar concentrator disclosed herein. In addition, the system may include a plurality of solar concentrators with each of the solar concentrators being the same type of solar concentrator. In other examples, many different types of solar concentrators may be present in the system.

In accordance with certain examples, methods of increasing the efficiency of a PV cell are disclosed. In certain examples, the method comprises providing concentrated optical radiation to a photovoltaic cell from a solar concentrator, the solar concentrator comprising any of the solar concentrators disclosed herein. In other examples, the method may further include embedding the PV cells in the solar concentrators to further increase the efficiency of the PV cells. Other methods of using the solar concentrators disclosed herein to increase the efficiency of PV cells and systems including PV cells will be readily selected by the person of ordinary skill in the art, given the benefit of this disclosure.

In accordance with certain examples, two or more waveguides may be optically coupled such that one of the waveguides absorbs light within a first wavelength range and at least one of the other waveguides absorbs light within a second wavelength range different from the first wavelength range. Devices that include two or more waveguides are referred to in certain instances herein as tandem devices. The tandem device may include two solar concentrators as described herein or may include a solar concentrator coupled to an existing thin film photovoltaic cell. Converting light to electrical current with multiple electrical bandgaps in a tandem configuration allows a higher fraction of the lights optical power to be converted to electrical power. In a tandem device comprised of a top system comprised of a concentrator collecting light to be converted at a high bandgap solar cell and a bottom system comprised of a lower electrical bandgap thin film photovoltaic, the requirements of current matching are alleviated as the two systems no longer need to be connected serially. In a serial configuration, the currents desirably match or the cell with the lowest current can limit the overall current and thus overall efficiency of the device.

In the configuration where the top solar cell is replaced by a top LSC, current matching is not necessary as electrodes are not shared. The LSC may be attached or otherwise coupled to one or more solar cells with a selected bandgap so a greater fraction of each photon's power will be extracted. Finally, the light that escapes the LSC from the bottom may still be captured and converted by the lower solar cell, so the losses in the LSC will be partially diminished. The combination of an LSC with a thin film solar cell provides numerous advantages including, but not limited to, a cheaper method to improve the module efficiency compared to just the underlying solar cell alone.

In certain examples, numerous different types of solar cells may be used with an LSC to provide a tandem device, and the exact type and nature of the solar cell is not critical. Illustrative solar cells for use with a LSC in a tandem device include, but are not limited to, chalcopyrite based (CuInSe₂, CuInS₂, CuGaSe₂), cadmium telluride (CdTe) amorphous, nanocrystalline, polycrystalline, or multicrystalline silicon, and amorphous silicon-germanium (SiGe) or germanium (Ge). The LSC may be used with any one or more of the LSC's described herein. In some examples, the LSC may be used with two or more thin film PV cells, whereas in some examples two or more LSC's may be used with a single thin film PV cell. Other combinations of LSC's and thin film PV cells to provide a tandem device will be readily selected by the person of ordinary skill in the art, given the benefit of this disclosure.

The following examples serve to illustrate some of the novel features, aspect and examples of the technology disclosed herein and should not be construed as limiting the scope of the appended claims.

### Example 1

A solar concentrator was produced as follows: DCTJB dye was used as a dopant and was added to a 3 micron film of AlQ3:rubrene (15% AlQ3:rubrene and 1% DCTJB w/w %) on a aluminum oxide substrate of dimensions 40 mm by 40 mm by 2 mm by vacuum thermal evaporation, a type of physical vapor deposition. In this process, three filled tungsten crucibles were individually heated to evaporate the three film components under high vacuum (10⁻⁴ Pa) whereupon the substrate was suspended at a distance of 50 cm and rotated at 1 Hz. The evaporation rate of each material was monitored by a quartz microbalance and controlled by a feedback circuit.

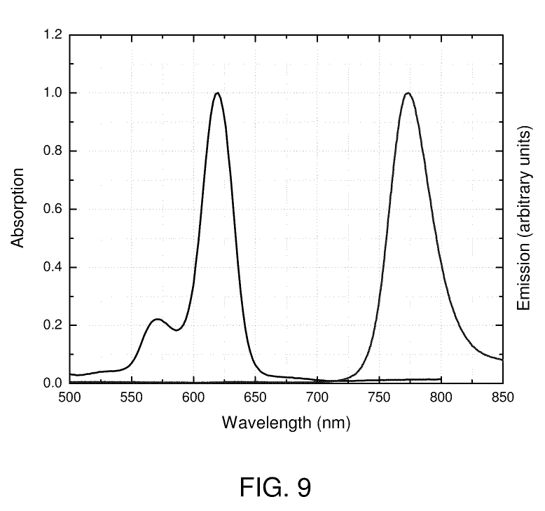

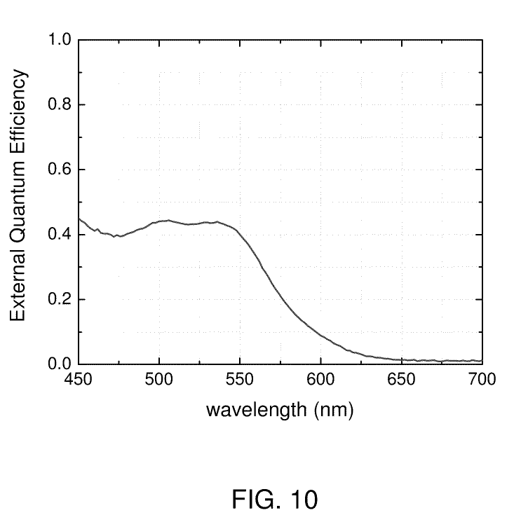

The addition of a small amount of DCTJB insured Förster energy transfer and red-shifting of the emission wavelength as shown in FIG. 9. The efficiencies for a solar concentrator comprised of AlQ3, rubrene and DCTJB are shown in FIG. 10. The left vertical axis shows the external quantum efficiency of the concentrator, defined as the ratio of photons which exit the concentrator edge faces to that incident upon the concentrator face. The eventual power conversion efficiency of the concentrator will vary depending on the type of solar cell and the manner in which it is attached to the edge faces of the concentrator.

### Example 2

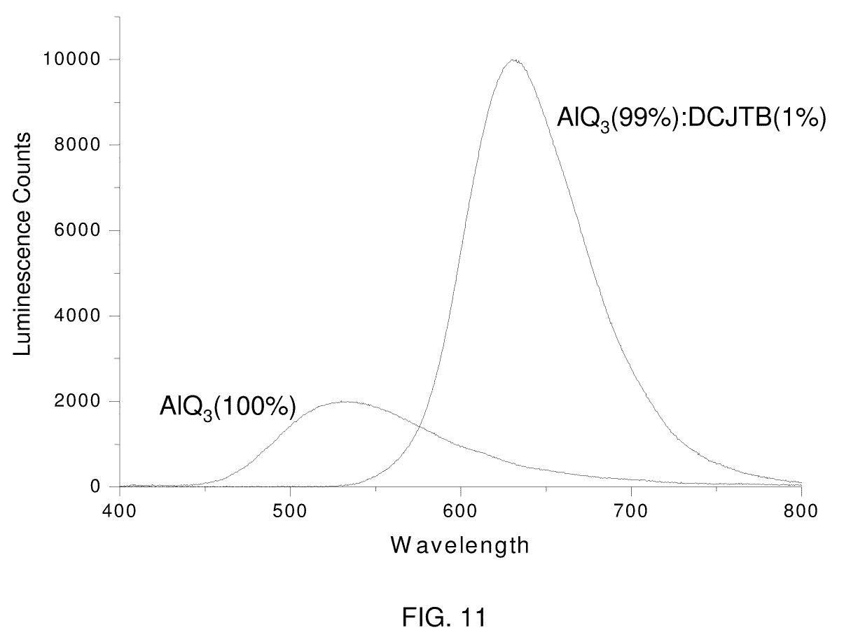

To improve the emission of a dye or chromophore with low photoluminescence efficiency, the dye or chromophore may be doped with one or more other dyes or chromophores with a higher photoluminescence efficiency Referring to FIG. 11, by doping AlQ3 with DCTJB at 1% ratio (w/w %), almost complete Förster energy transfer is achieved, which results in almost all, or all, absorbed photons being radiated rather than lost to non-radiative transitions as the photoluminescence efficiency of DCJTB is approximately four times greater than that of AlQ3. The manner in which this film was made is identical to that described in Example 1.

### Example 3

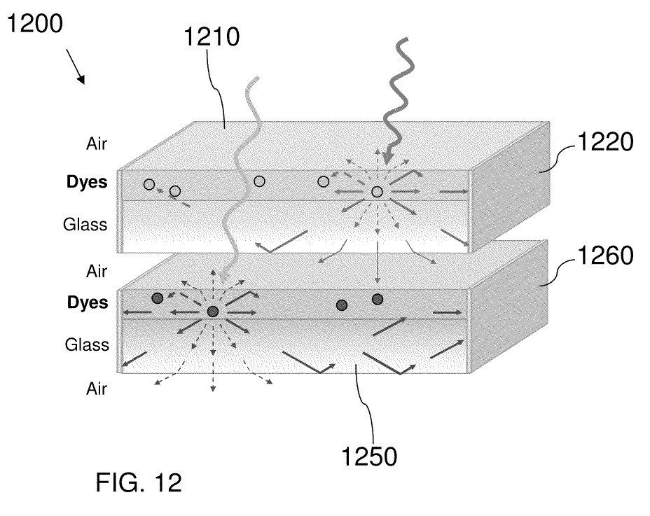

A tandem luminescent solar concentrator (LSC) may be produced stacking two or more waveguides onto each other or otherwise optically coupling two or more waveguides. Referring to FIG. 12, a tandem luminescent solar concentrator 1200 comprises a first waveguide 1210 disposed or stacked on a second waveguide 1250. The top waveguide 1210 may be configured to concentrate visible radiation on a solar cell 1220 coupled to the waveguide 1210. Solar cell 1220 may be, for example, a GalnP solar cell. The bottom waveguide 1250 may be configured to concentrate a different wavelength range of radiation on a solar cell 1260 coupled to the waveguide 1250. For example, the waveguide 1250 may include a chromophore that is configured to absorb radiation below 950 nm and provide such radiation to the solar cell 1260. The solar cell 1260 may be, for example, a silicon solar cell.

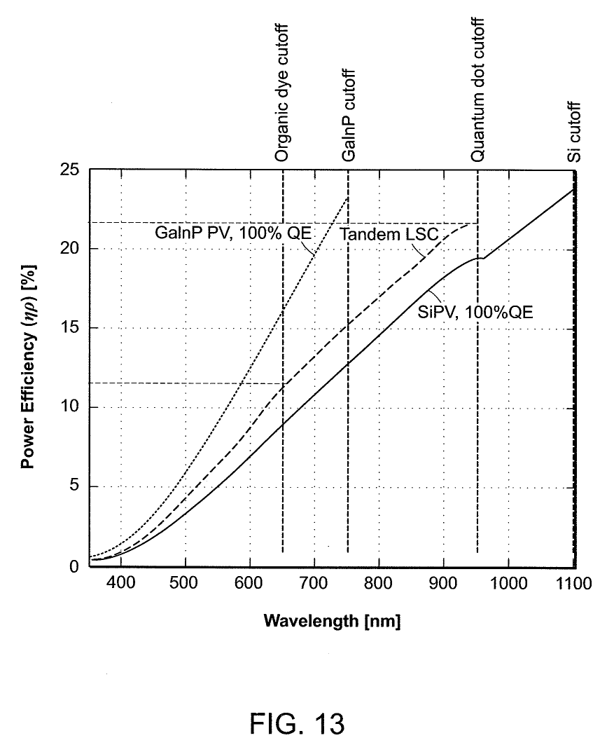

The projected performance of the tandem LSC is shown in FIG. 13. For a quantum efficiency of 70% in each waveguide, the total power efficiency of the combined waveguides is about 21%. The absorption cutoff for the top waveguide 1210 is taken to be 650 nm, and the absorption cutoff for the bottom waveguide 1250 is taken to be 950 nm. The model assumes a 100 nm shift between absorption and emission in the top waveguide 1210 and a 150 nm shift between absorption and emission in the bottom waveguide 1250 to lower self absorption. The model is based on the following description.

### Example 4

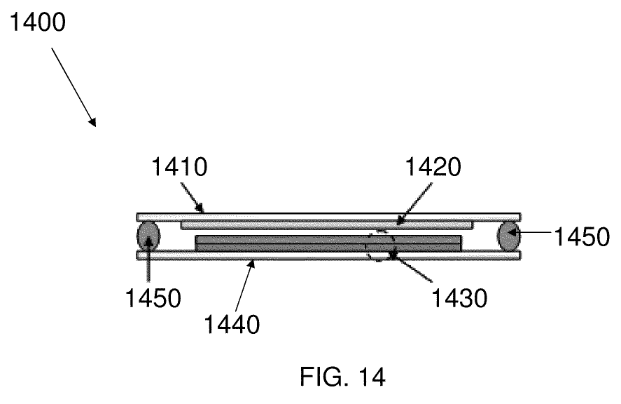

A key stability concern in LSCs is the emissive dye. This dye may be, for example a red or infrared emitter. Since work on LSCs was largely abandoned there has been significant investment in the research and development of organic light emitting devices (OLEDs). This work generated red OLEDs that now routinely exhibit half-lives exceeding 300,000 hours, or thirty years. Progress in OLED stability has been achieved through advances in dye molecule design and packaging. Both of these technologies are directly applicable to LSCs. An LSC may include one or more dessicants or getters to reduce the exposure of the dye to oxygen or other air sources, which may reduce the overall lifetime of the LSC. One example of this configuration is shown in FIG. 14. The LSC 1400 comprises a top plate 1410, a dessicant layer 1420, a dye 1430, a bottom plate 1440 and a sealant 1450 reducing or preventing ingress of oxygen into the body of the LSC 1400. The LSC 1400 may be coupled on one end to a PV cell (not shown). Illustrative dessicants include, but are not limited to, cellulose acetates, epoxies, phenoxies, siloxanes, methacrylates, sulfones, phthalates, amides, acrylates, methacrylates, cyclized polyisoprenes, polyvinyl cinnamates, epoxies, silicones, adhesives, and radiation-curable binders selected from the group consisting of radiation-curable photoresist compositions. The exact thickness of the dessicant layer may vary, and preferably the dessicant does not substantially interfere with absorption of radiation by the dye.

A table showing the stability of Universal Display Corporation's set of phosphorescent dye molecules (www.universaldisplay.com) is shown below.

| | η_{Q} | η_{PL}* | Lifetime to 50% |
|---|---|---|---|
| blue | 11% | 46% | 17,500 hrs @ 200 cd/m² |
| green | 19% | 71% | 250,000 hrs @ 1000 cd/m² |
| red | 20% | 80% | 330,000 hrs @ 1000 cd/m² |

### Example 5

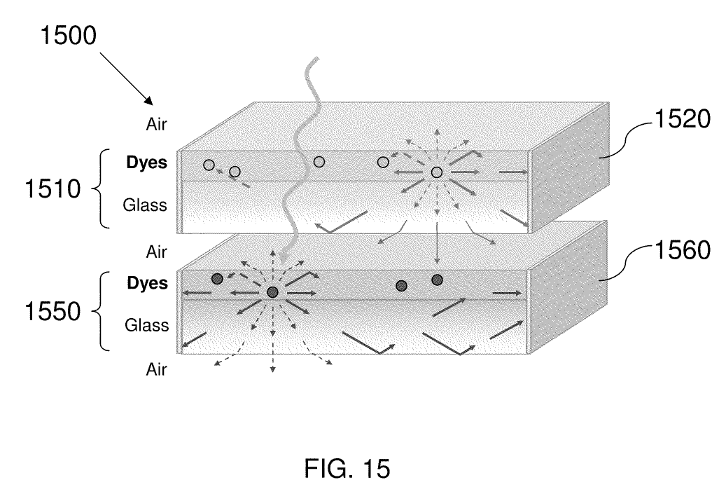

A tandem luminescent solar concentrator (LSC) may be produced stacking two waveguides onto each other. Referring to FIG. 15, a tandem luminescent solar concentrator 1500 comprises a first waveguide 1510 disposed or stacked on a second waveguide 1550. The top waveguide 1510 may be configured to concentrate visible radiation on a solar cell 1520 coupled to the waveguide 1510. Solar cell 1520 may be, for example, a GalnP solar cell. The bottom waveguide 1550 may be configured to concentrate a different wavelength range of radiation on a solar cell 1560 coupled to the waveguide 1550. In one embodiment, the solar cell 1560 may be a GaAs solar cell.

Top waveguide 1510 may be glass coated with an evaporated dye layer of composition tris-(8-hydroxyquinoline) aluminum (68.5%):rubrene (30%): 4-(dicyanomethylene)-2-t-butyl-6-(1,1,7,7-tetramethyljulolidyl-9-enyl)-4H-pyran (1.5%) (structures (III), (IV) and (V), respectively).

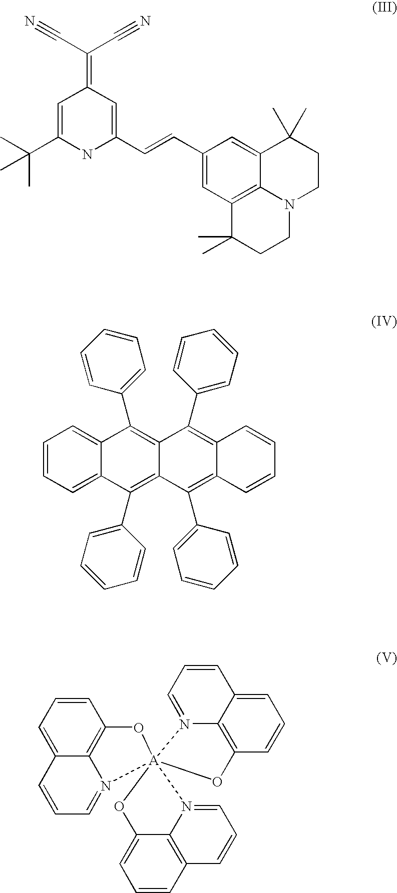

Bottom waveguide 1550 is glass coated with an evaporated dye layer of composition tris-(8-hydroxyquinoline) aluminum (94%): 4-(dicyanomethylene)-2-t-butyl-6-(1,1,7,7-tetramethyljulolidyl-9-enyl)-4H-pyran (1.5%) (2%):platinum tetraphenyltetrabenzoporphyrin(4%) (structures (V), (III) and (VI), respectively).

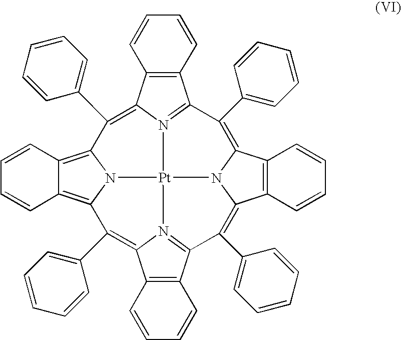

### Example 6

Experience with OLEDs has demonstrated that organic dyes can be stable for long periods if their package is extremely impermeable to oxygen and water. For example, the common OLED package shown in FIG. 12 employs glass and metal surfaces with an epoxy seal and a desiccant. In the LSC application, it is also desirable to protect both surfaces of the waveguide from scratches and defects that might promote scattering losses. Consequently, the LSC may be packaged in several ways to provide protection.

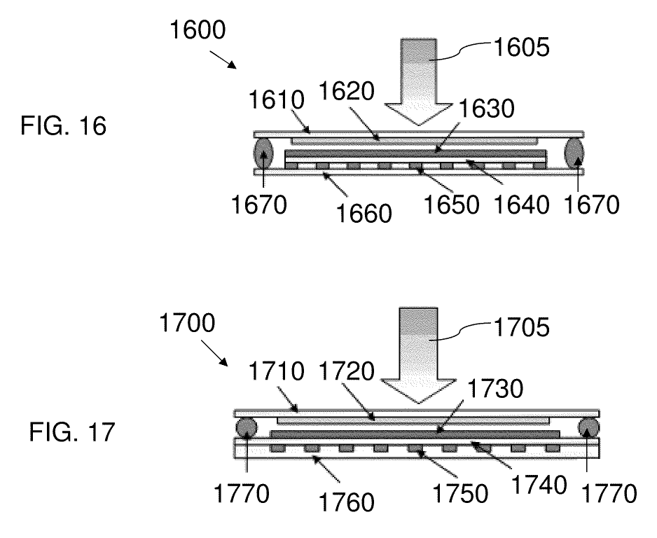

Referring to FIG. 16, a device 1600 comprises a top layer 1610, a dessicant layer 1620, at least one dye 1630 (which may be in a film), a substrate 1640, a plurality of photovoltaic cells, such as photovoltaic cell 1650, a bottom layer 1660 and a spacer/sealant 1670. The device 1600 is configured to absorb incident radiation 1605. In some examples, the top layer 1610, the substrate 1640 and the bottom layer 1660 may each be, or may include, glass. In other examples, the bottom layer 1660 may be a reflective surface, e.g., a mirror, to enhance the absorption efficiency of the device 1600.

Referring to FIG. 17, a device 1700 comprises a top layer 1710, a dessicant layer 1720, at least one dye 1730 (which may be in a film), a substrate 1740, a plurality of photovoltaic cells, such as photovoltaic cell 1750, a bottom layer 1760 and a spacer/sealant 1770. The device 1700 is configured to absorb incident radiation 1705. In some examples, the top layer 1710 and the substrate 1740 may each be, or may include, glass. In other examples, the bottom layer 1760 and/or the top layer 1710 may be replaced by a low refractive index polymer, and the glass substrate 1740 itself may be used to protect the dye 1730. This approach may reduce the overall weight of the device.

### Example 7

The self-absorption ratio, S, between the peak absorption of a given solar concentrator and its absorption at its emissive wavelength is a rough estimate of the maximum possible G. DCJTB belongs to the DCM class of laser dyes, characterized by large Stokes shifts and red emission with near unity quantum efficiency.

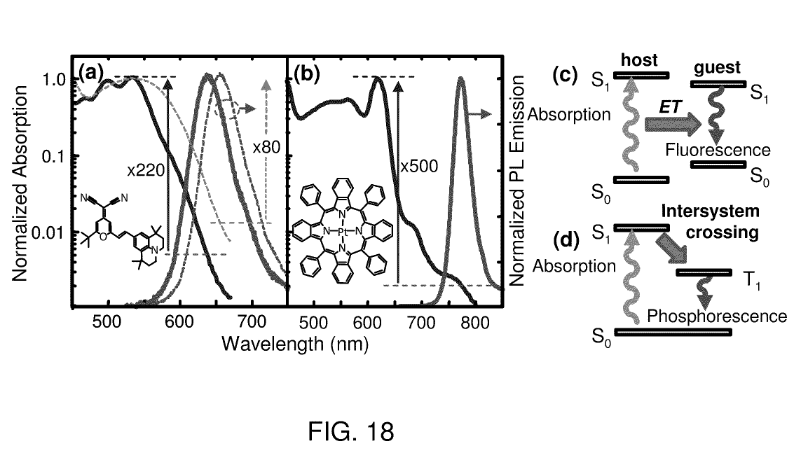

As shown in FIG. 18A, the self-absorption ratio for a DCJTB-based solar concentrator is approximately S=80. To control the concentration of DCJTB, it was co-deposited with the host material tris(8-hydroxyquinoline) aluminum (AlQ3), which is known to form stable amorphous films. The self-absorption ratio is enhanced when AlQ3 is used as the host, because both AlQ3 and DCJTB are polar molecules. The polar environment red-shifts the DCJTB photoluminescence (PL) via the solid state solvation effect, which is employed in OLEDs to adjust the emission color.

Förster energy transfer may be used to reduce the required concentration of the emissive dye. For example, in the rubrene-based solar concentrator of FIG. 18A, we employ rubrene and DCJTB in a 20:1 ratio. Förster energy transfer from rubrene to DCJTB increases the self-absorption ratio of the rubrene-based OSC relative to the DCJTB-based OSC. Rubrene is non polar, however, and together with a slight reduction in the DCJTB concentration, this causes the DCJTB PL to shift approximately 20 nm back towards the blue.

Solar concentrators may also be produced using Pt(TPBP), which is phosphorescent in the infrared at wavelength of 770 nm with a PL efficiency of approximately 50%. It emits from a weakly-allowed triplet state relaxation. Compared to conventional fluorescent dyes, the emissive state of phosphorescent dyes is only weakly absorptive and typically exhibit large Stokes shifts. Indeed, the self-absorption ratio for the Pt(TPBP)-based OSC is approximately S=500; see FIG. 18B. The absorption of Pt(TPBP) is dominated by strong transitions from the Soret band at a wavelength of 430 nm and the Q band at a wavelength of 611 nm. To complete the absorption spectrum of Pt(TPBP)-based solar concentrators, DCJTB was added to fill in the Pt(TPBP) absorption spectrum and transfer energy to Pt(TPBP). Förster energy transfer and phosphorescence are illustrated schematically in FIGS. 18C and 18D, respectively.

The optical quantum efficiency (OQE), defined as the fraction of photons emitted from the edges of the OSC substrates, was determined within an integrating sphere. In an organic film refractive index of n=1.7 where all photons are re-emitted isotropically, approximately 80% of the photons are re-emitted into waveguide modes in the organic film or glass substrate. In the absence of self-absorption or scattering losses, these photons emerge from the edges of the solar concentrator and couple to the PV cell. The remaining photons are not subject to total internal reflection and are emitted into air through the top and bottom faces of the solar concentrator. Edge and facial emission may be distinguished by selectively blocking edge emission using black marker and tape.

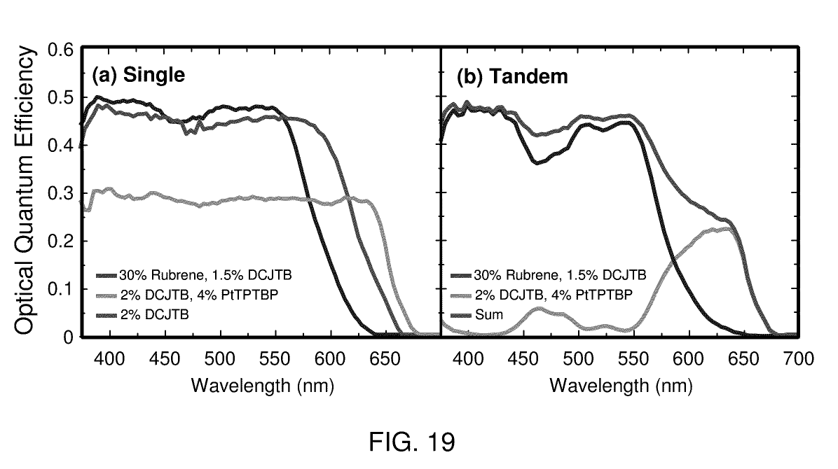

The OQEs of the single waveguide concentrators at low geometric concentration (G=3) are compared in FIG. 19A. A tandem waveguide solar concentrator was constructed using the rubrene-based solar concentrator on top to collect blue and green light and the Pt(TPBP)-based solar concentrator on the bottom to collect red light. Together, this tandem concentrator combines higher efficiency collection in the blue and green with lower efficiency performance further into the red; see FIG. 19B.

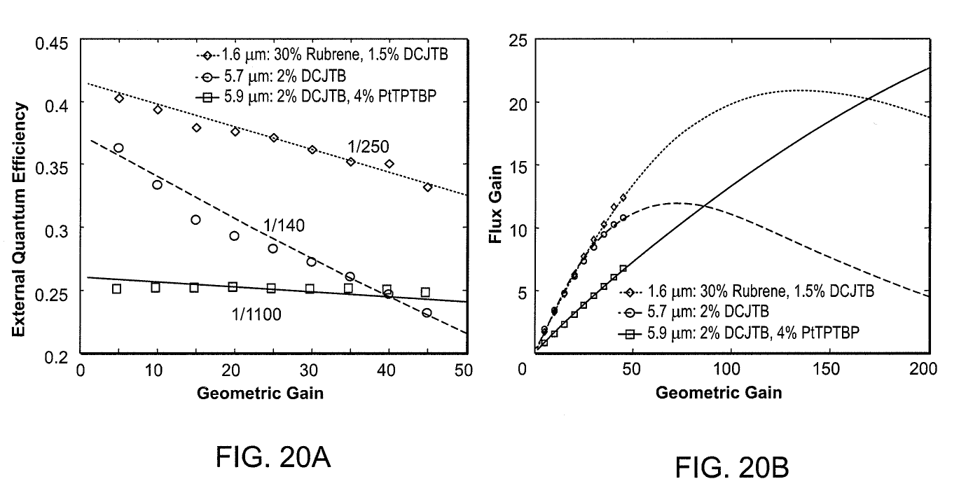

The external quantum efficiency (EQE) is the number of harvested electrons per incident photon and includes the coupling losses at the PV interface and the quantum efficiency of the PV. To obtain the EQE in the range G<50, the films were evaporated onto a 100 mm×100 mm×1 mm glass substrate with n=1.72. A 125 mm×8 mm strip of a Sunpower solar cell was attached to one entire edge of the substrate using EpoTek 301 epoxy. Note that the solar cell possesses an antireflection coating optimized for coupling from air. The remaining edges were blackened with marker to prevent reflections. The effect of increasing G is measured by sweeping a monochromatic excitation spot perpendicular to the attached solar cell and normalizing by solid angle. FIG. 20A shows the dependence of the EQE with G for each of the films, taken at the peak wavelength of the final absorbing dye (wavelength of 534 nm for DCJTB and wavelength of 620 nm for Pt(TPBP)). The DCJTB-based concentrator shows the strongest self-absorption. The self-absorption is lower in the rubrene-based concentrator, consistent with the spectroscopic data in FIG. 18A. Finally, the Pt(TPBP)-based concentrator shows no observable self-absorption loss for G<50. The data matches the theoretical performance assuming self-absorption ratios of S=140, S=250 and S 1100, for DCJTB, rubrene and Pt(TPBP)-based concentrators, respectively.

In FIG. 20B, the flux gain, F, for the three films coupled to bandgap-matched solar cells are compared utilizing the flux gain equation (flux=(geometric gain*efficiency of concentrator)/(efficiency of PV cell)). For G<50, all three films showed increasing flux gain with G. The power conversion efficiency was obtained from the optical quantum efficiency by integrating the product of the OQE, the AM1.5G spectrum and the external quantum efficiency of the solar cell as described, for example, in J. Palm et al., Solar Energy, 77 (2004) 757-765 and/or in S. H. Demtsu and J. R. Sites, “Quantification of losses in thin-film CdS/CdTe solar cells”, Thirty-first IEEE Photovoltaic Specialists Conference, 2005, pp. 347-350. Concentrators with emission from DCJTB may be paired with GaInP solar cells; those with emission from Pt(TPBP) may be paired with GaAs. The resulting power conversion efficiencies are listed in the table below.

| | Power conversion | Flux gain at | Projected max. |
|---|---|---|---|
| LSC | efficiency at G = 3, 50 | G = 50 | flux gain |
| DCJTB | 5.9%, 4.0% | 10 | 12 at G = 70 |
| rubrene | 5.5%, 4.7% | 12 | 21 at G = 130 |
| Pt(TPBP) | 4.1%, 4.1% | 6 | 32 at G = 500 |
| Tandem LSC | 6.8%, 6.1% | — | — |
| Tandem | 11.9%, 11.1% | 12 | 21 at G = 130 |
| LSC-CdTe PV | | | |
| Tandem | 14.5%, 13.8% | 12 | 21 at G = 130 |
| LSC-CIGS PV | | | |

The flux gains demonstrated above enable the use of high performance PV cells in low cost systems. A large flux gain may be most advantageous in >1 MW scale PV installations where the cost of the solar cells is paramount. In addition, the power conversion efficiency may be increased, for example, using a tandem LSC-thin film photovoltaic cell.

### Example 8

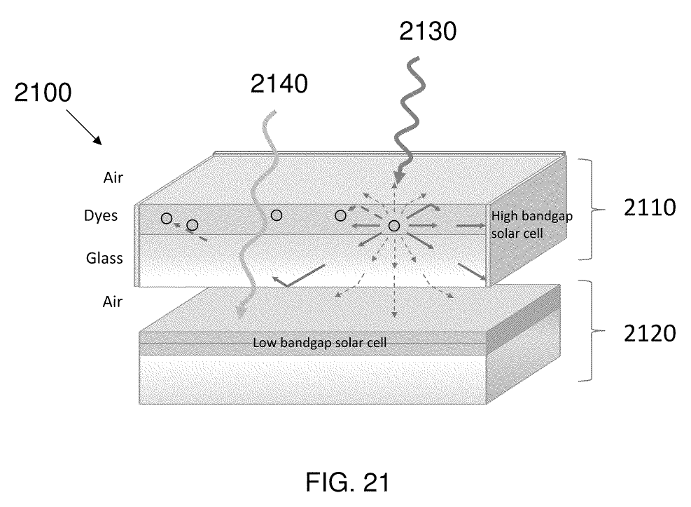

A solar concentrator may be coupled to a thin film photovoltaic cell as shown in FIG. 21. The device 2100 includes a solar concentrator 2110 coupled to a thin film PV cell 2120. Each of the devices 2110 and 2120 may be selected to absorb different wavelength ranges of light. For example, concentrator 2110 may be designed as a high bandgap solar cell such that certain light wavelengths 2130 are absorbed and other light wavelengths 2140 are transmitted through the device 2110 and absorbed by device 2120.

When introducing elements of the aspects, embodiments and examples disclosed herein, the articles “a, “an,” “the” and “said” are intended to mean that there are one or more of the elements. The terms “comprising,” “including” and “having” are intended to be open-ended and mean that there may be additional elements other than the listed elements. It will be recognized by the person of ordinary skill in the art, given the benefit of this disclosure, that various components of the examples can be interchanged or substituted with various components in other examples.

Although certain aspects, examples and embodiments have been described above, it will be recognized by the person of ordinary skill in the art, given the benefit of this disclosure, that additions, substitutions, modifications, and alterations of the disclosed illustrative aspects, examples and embodiments are possible.

What is claimed is:

1. A solar concentrator comprising a substrate and at least first and second closely spaced chromophores disposed on or in the substrate in a manner to receive at least some optical radiation, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore.

2. The solar concentrator of claim 1, in which the substrate is a glass comprising a refractive index of at least 1.7.

3. The solar concentrator of claim 1, in which the second chromophore emits light by phosphorescence.

4. The solar concentrator of claim 1, further comprising an effective amount of a red-shifting agent to shift an emission wavelength range of the second chromophore to a higher wavelength range

5. The solar concentrator of claim 1, in which at least one of the first and second chromophores is an organometallic compound.

6. The solar concentrator of claim 5, in which the organometallic compound is a porphyrin compound.

7. The solar concentrator of claim 1, further comprising at least one wavelength selective mirror disposed on the substrate, the wavelength selective mirror configured to transmit incident light in a first wavelength range and to reflect incident light in a second wavelength range.

8. The solar concentrator of claim 1, further comprising a polar matrix in which at least one of the first and second chromophores is disposed.

9. The solar concentrator of claim 1, further comprising a first photovoltaic cell optically coupled to the solar concentrator.

10. The solar concentrator of claim 9, further comprising a second photovoltaic cell optically coupled to the solar concentrator, wherein the efficiency of the first and second photovoltaic cells are different.

11. A solar concentrator comprising:
a substrate; and
a plurality of chromophores disposed on or in the substrate in a manner to receive at least some optical radiation, the plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores.

12. The solar concentrator of claim 11, in which the substrate is a glass comprising a refractive index of at least 1.7.

13. The solar concentrator of claim 11, in which the terminal chromophore emits light by phosphorescence.

14. The solar concentrator of claim 11, further comprising an effective amount of a red-shifting agent to shift an emission wavelength range of the terminal chromophore to a higher wavelength range.

15. The solar concentrator of claim 11, in which at least one of the plurality of chromophores is an organometallic compound.

16. The solar concentrator of claim 15, in which the organometallic compound is a porphyrin compound.

17. The solar concentrator of claim 11, further comprising at least one wavelength selective mirror disposed on the substrate, the wavelength selective mirror configured to transmit incident light in a first wavelength range and to reflect incident light in a second wavelength range.

18. The solar concentrator of claim 11, further comprising a polar matrix in which at least one of the plurality of chromophores is disposed.

19. The solar concentrator of claim 11, further comprising a first photovoltaic cell optically coupled to the solar concentrator.

20. The solar concentrator of claim 19, further comprising a second photovoltaic cell optically coupled to the solar concentrator, wherein the efficiency of the first and second photovoltaic cells are different.

21. A tandem device comprising the solar concentrator of claim 1 coupled to a thin film photovoltaic cell, wherein the solar concentrator and the thin film photovoltaic cell are each selected to have different bandgaps.
